(19) United States
(12) Patent Application Publication
(10) Pub. No.: US 2023/0420506 A1
(43) Pub. Date: Dec. 28, 2023

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Wei Ju LEE, Kaohsiung City (TW); Chun-Fu CHENG, Hsinchu County (TW); Chung-Wei WU, Hsinchu County (TW); Zhiqiang WU, Hsinchu County (TW)

(73) Assignee: TAIWAN SEMICONDUCTOR MANUFACTURING COMPANY, LTD., Hsinchu (TW)

(21) Appl. No.: 17/847,075

(22) Filed: Jun. 22, 2022

(51) Int. Cl. H01L 29/06; H01L 29/423; H01L 29/775; H01L 29/417; H01L 29/66; H01L 29/786; H01L 21/8234

(52) U.S. Cl. CPC H01L 29/0673; H01L 29/42392; H01L 29/775; H01L 29/41733; H01L 29/66439; H01L 29/78618; H01L 29/78696; H01L 29/0649; H01L 21/823412; H01L 21/823418; H01L 21/823481

(57) ABSTRACT

A method includes forming a channel region above a (110)-orientated substrate and having a length extending in a <100> direction; epitaxial growing a plurality of source/drain regions on either side the channel region; forming a gate structure surrounding the channel region; forming a plurality of source/drain contacts on the source/drain regions.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-15C illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the components in the IC structure will result in a smaller contact area between the source/drain contact and the epitaxial source/drain region, which results in a worse device performance due to a smaller plateau of the epitaxial source/drain region. In order to improve the device performance, a plateau of the epitaxial source/drain region may be enlarged. However, the enlarged plateau of the epitaxial source/drain region may cause a bridge between adjacent two epitaxial source/drain regions, and thereby reducing the yield of the IC structure.

Therefore, the present disclosure in various embodiments provides an epitaxial source/drain region formed on a <110> channel over a (110) orientation substrate, and thus the epitaxial source/drain region can have a square bar cross-sectional profile to provide more contact area to contact an overlying source/drain contact and have a same width at different heights thereon, which in turn allows for achieving a larger metal contact area and a less epitaxial source/drain region. The larger metal contact area can improve resistance of the device, and the less epitaxial source/drain region can improve a source/drain region merge window and reduce capacity of the device, and thus the device performance may be improved.

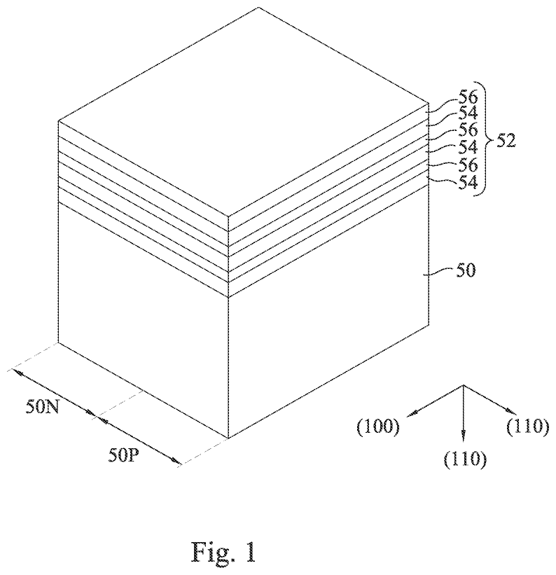

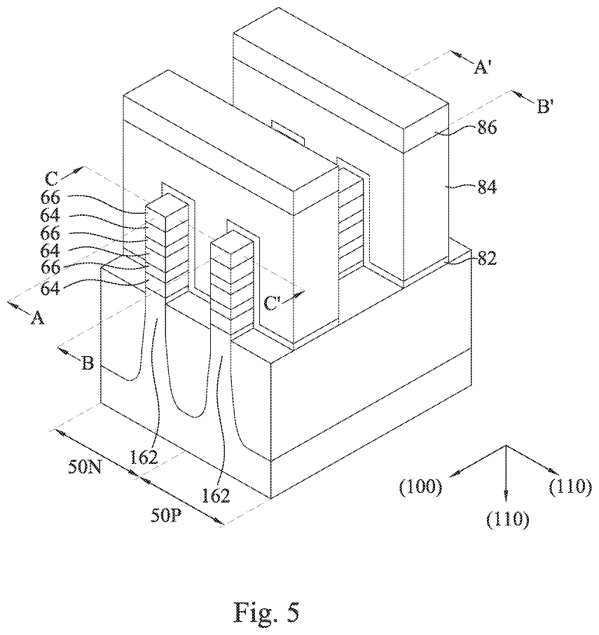

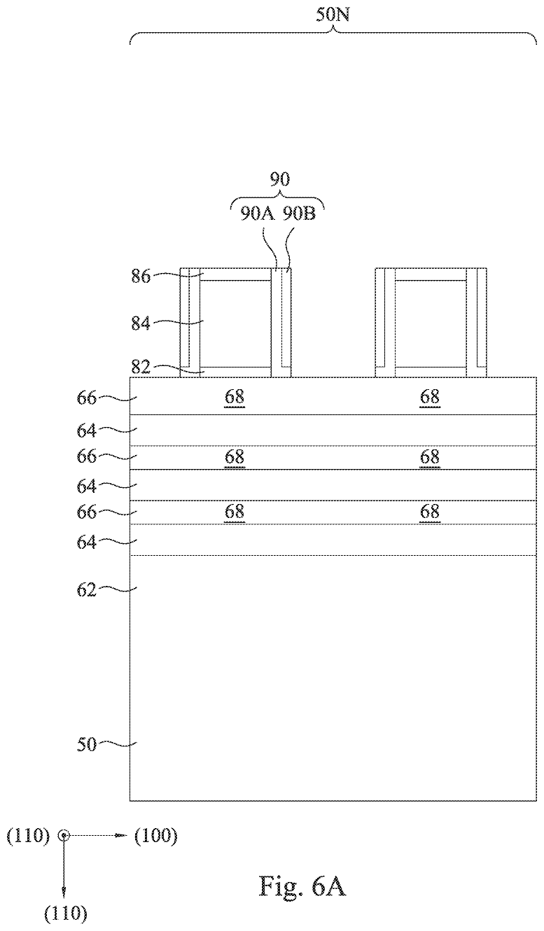

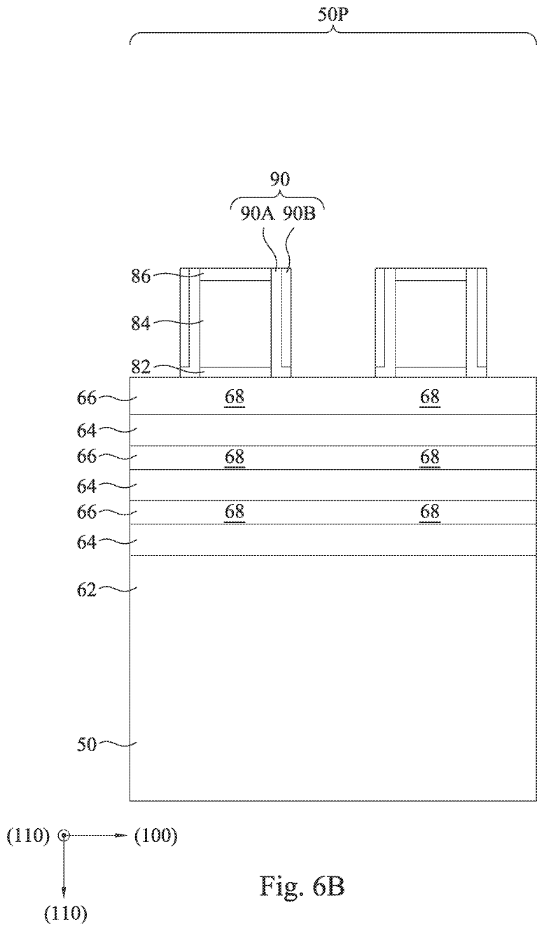

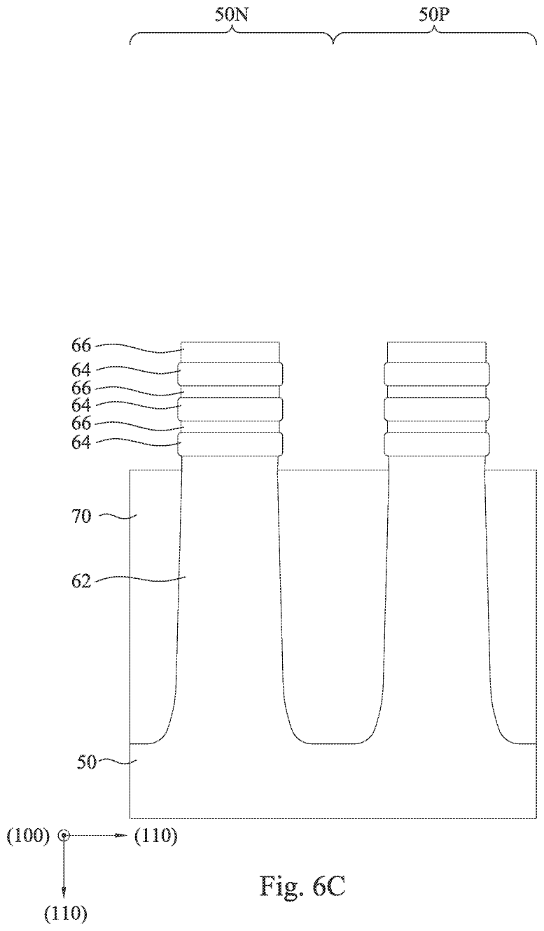

FIGS. 1, 2, 3A, 4, 5, 6A-8C, and 9A-15C are views of intermediate stages in the manufacturing of nano-FETs in accordance with some embodiments. FIGS. 1, 2, 3A, 4, and 5 are three-dimensional views. FIGS. 6A, 7A, 8A, 9A, 10A, 11A, 12A, 13A, 14A, and 15A illustrate reference cross-section A-A′ illustrated in FIG. 5. FIGS. 6B, 7B, 8B, 9B, 10B, 11B, 12B, 13B, 14B, and 15B illustrate reference cross-section B-B′ illustrated in FIG. 5. FIGS. 6C, 7C, 8C, 9C, 10C, 11C, 12C, 13C, 14C, and 15C illustrate reference cross-section C-C′ illustrated in FIG. 5.

With reference to FIG. 1, a substrate 50 is provided for forming nano-FETs. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (not separately illustrated), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

The substrate 50 may be lightly doped with a p-type or an n-type impurity. An anti-punch-through (APT) implantation may be performed on an upper portion of the substrate 50 to form an APT region. During the APT implantation, impurities may be implanted in the substrate 50. The impurities may have a conductivity type opposite from a conductivity type of source/drain regions that will be subsequently formed in each of the n-type region 50N and the p-type region 50P. The APT region may extend under the source/drain regions in the nano-FETs. The APT region may be used to reduce the leakage from the source/drain regions to the substrate 50. In some embodiments, the doping concentration in the APT region may be in the range of about 10¹⁸ cm⁻³ to about 10¹⁹ cm⁻³.

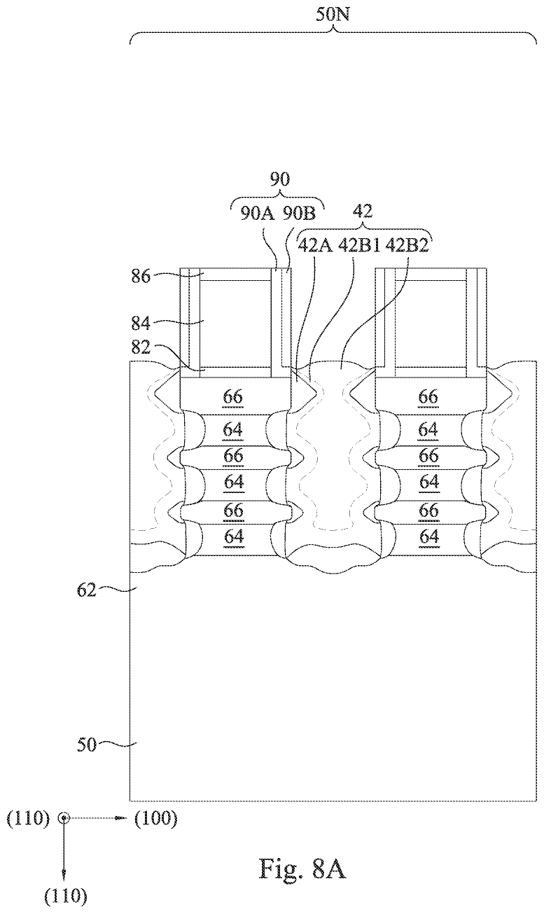

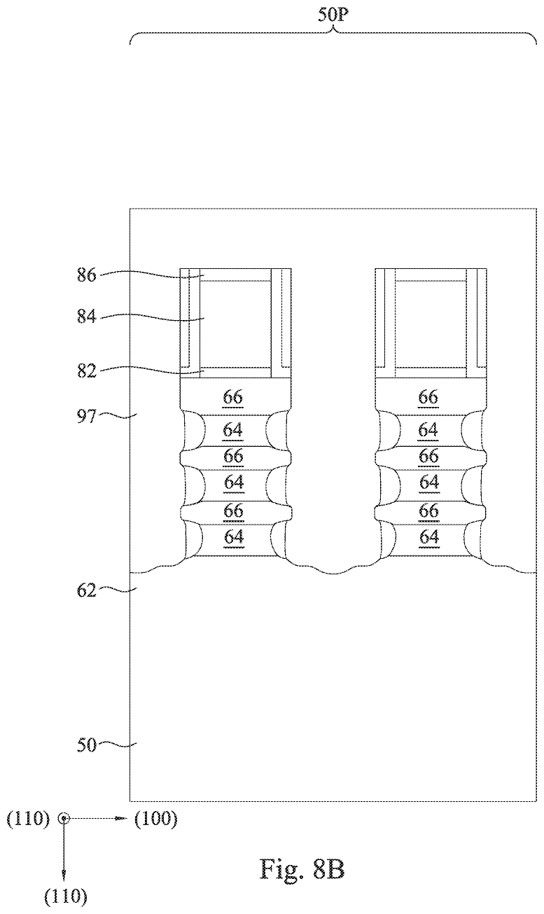

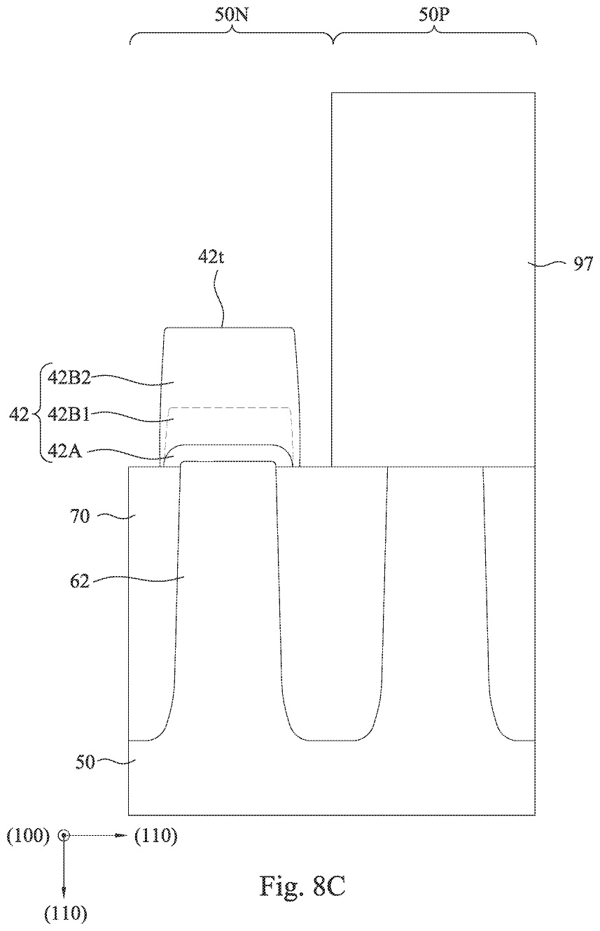

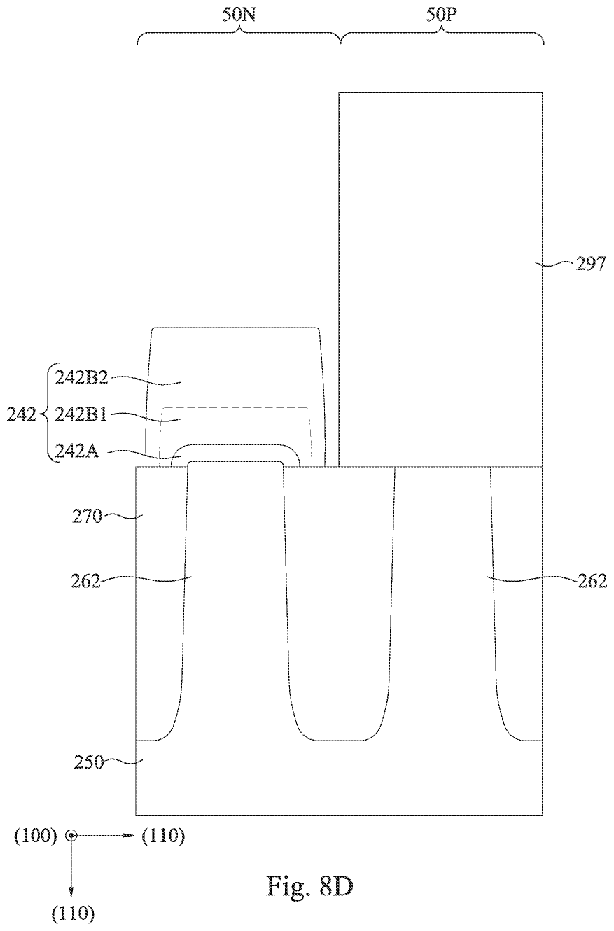

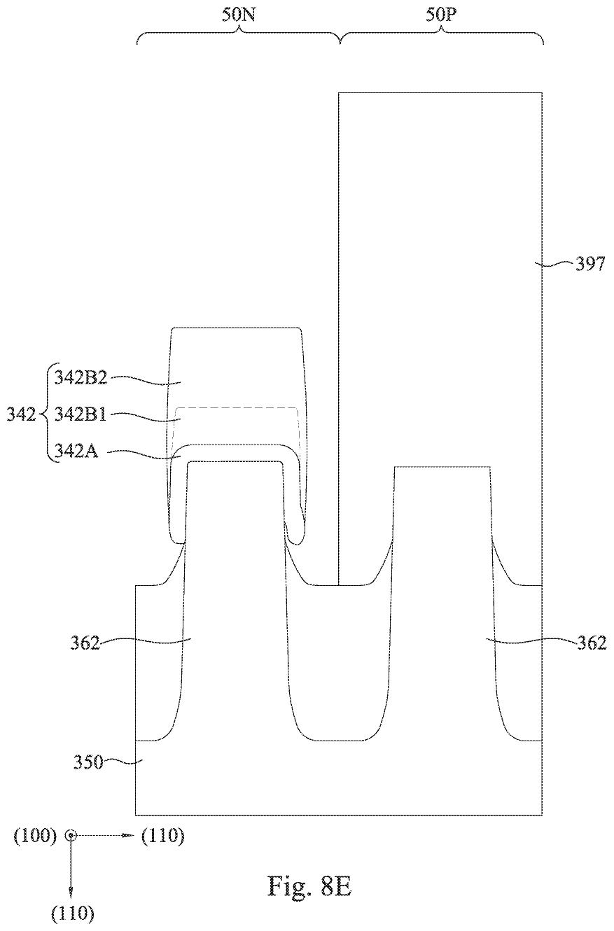

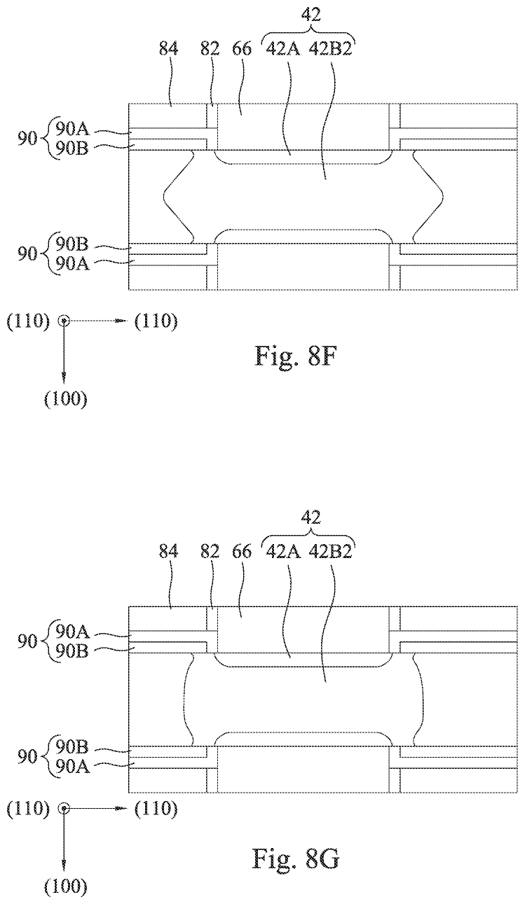

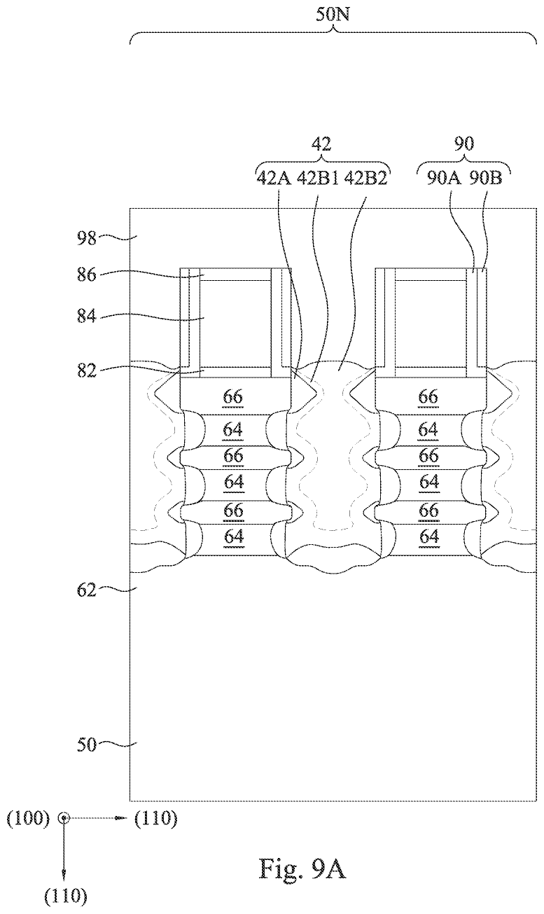

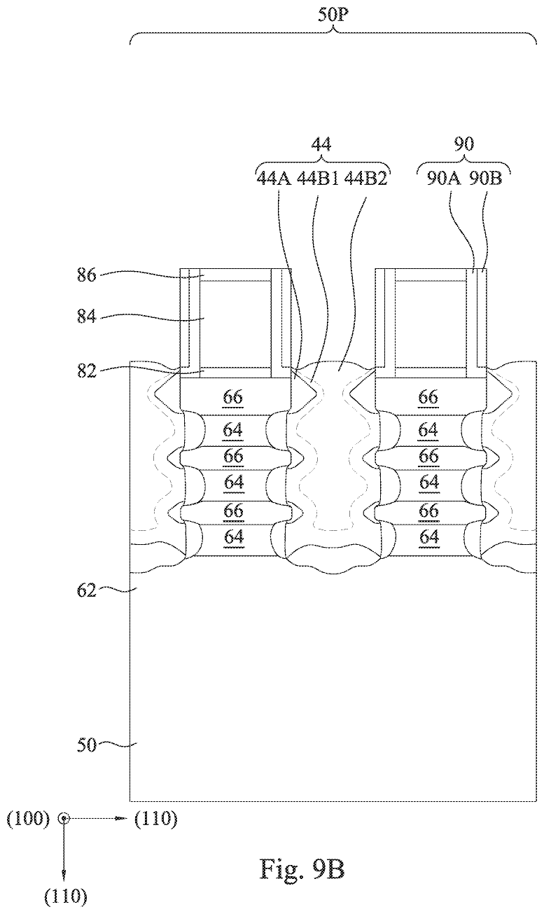

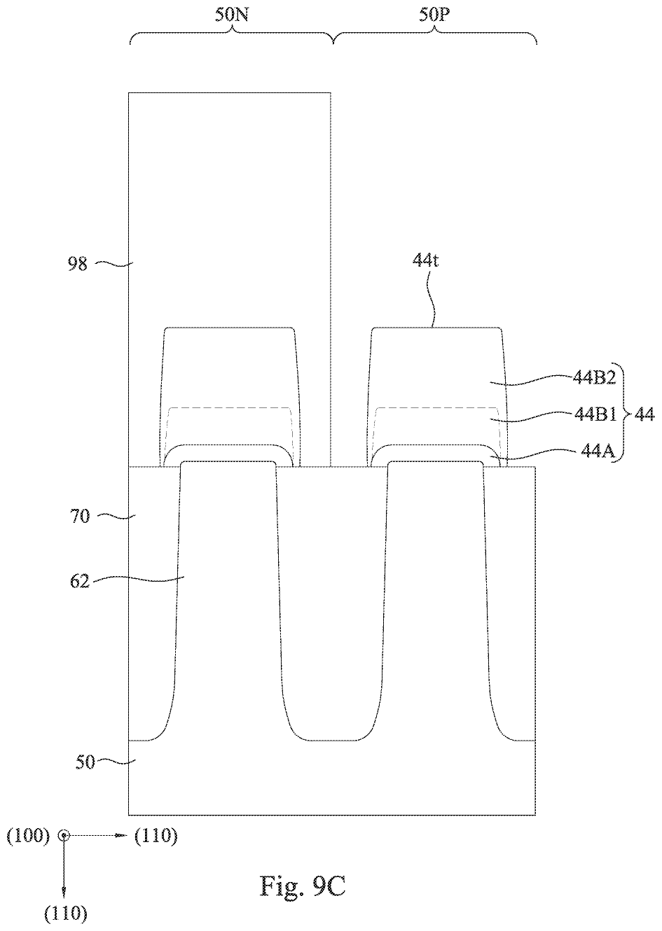

In some embodiments, the substrate 50 has (110) surface orientation. This surface orientation can be used to control the orientation of the layers (e.g., a multi-layer stack 52) which are formed above the substrate 50. For example, the multi-layer stack 52 including alternating first semiconductor layers 54 and second semiconductor layers 56 formed on the (110) surface orientation substrate 50 also can have (110) surface orientation. The (110) surface orientation semiconductor layers 56 can act as channel layers (see FIGS. 6A and 6B) and improves device performance (I_{deff}) due to a higher hole mobility on <100>/(110) than <110>/(100) and <110>/(110). Furthermore, the arrangement of some layers which are above the substrate 50 may be influenced by the surface orientations of the substrate 50. For example, the (110) surface orientation of the substrate 50 can be used to assist in formation of quadrilateral cross-sectional source/drain (S/D) structure formed on the second semiconductor layers 56 as shown in FIGS. 8A, 8C, 9B, and 9C. In some embodiments, the substrate 50 is on a wafer having a notch directed at the <110> direction. A more detailed description will be described later.

In some embodiments, the first semiconductor layers 54 of the multi-layer stack 52 are formed of a first semiconductor material, and the second semiconductor layers 56 of the multi-layer stack 52 are formed of a second semiconductor material. The semiconductor materials may each be selected from the candidate semiconductor materials of the substrate 50. In the illustrated embodiment, the multi-layer stack 52 includes three layers of each of the first semiconductor layers 54 and the second semiconductor layers 56. It should be appreciated that the multi-layer stack 52 may include any number of the first semiconductor layers 54 and the second semiconductor layers 56.

In some embodiments, and as will be subsequently described in greater detail, the first semiconductor layers 54 will be removed and the second semiconductor layers 56 will patterned to form channel regions for the nano-FETs in the n-type region 50N and the p-type region 50P. The first semiconductor layers 54 are sacrificial layers (or dummy layers), which will be removed in subsequent processing to expose the top surfaces and the bottom surfaces of the second semiconductor layers 56. The first semiconductor material of the first semiconductor layers 54 is a material that has a high etching selectivity from the etching of the second semiconductor layers 56. In some embodiments, the first semiconductor material of the first semiconductor layers 54 may be a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without removing the second semiconductor layers 56. For example, the first semiconductor material of the first semiconductor layer may be made of silicon germanium, and the second semiconductor material of the second semiconductor layers 56 may be made of silicon.

Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. Each of the layers may have a small thickness, such as a thickness in a range of about 5 nm to about 30 nm. In some embodiments, some layers (e.g., the second semiconductor layers 56) are formed to be thinner than other layers (e.g., the first semiconductor layers 54). For example, in embodiments in which the first semiconductor layers 54 are sacrificial layers (or dummy layers) and the second semiconductor layers 56 are patterned to form channel regions for the nano-FETs in both the n-type region 50N and the p-type region 50P, the first semiconductor layers 54 can have a first thickness and the second semiconductor layers 56 can have a second thickness, with the second thickness being from about 30% to about 60% less than the first thickness. Forming the second semiconductor layers 56 to a smaller thickness allows the channel regions to be formed at a greater density.

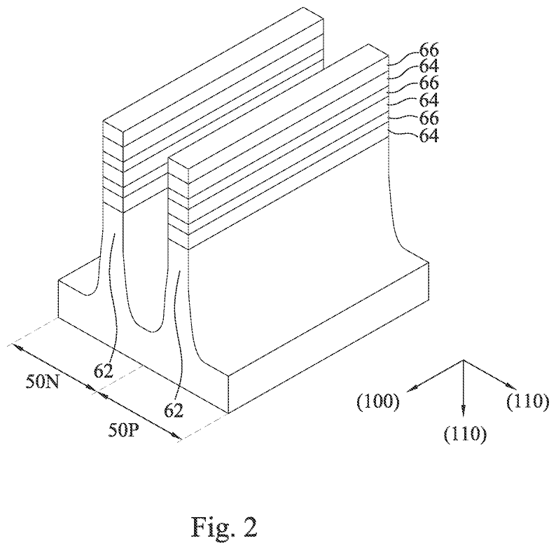

With reference to FIG. 2, trenches are patterned in the substrate 50 and the multi-layer stack 52 to form fins 62, first nanostructures 64, and second nanostructures 66. The fins 62 are semiconductor strips patterned in the substrate 50. In some embodiments, the fins 62 extend along the <100> direction on the (110) orientation substrate 50. The first nanostructures 64 and the second nanostructures 66 include the remaining portions of the first semiconductor layers 54 and the second semiconductor layers 56, respectively. The trenches may be patterned by any acceptable etch process, such as a reactive ion etch (RIE), neutral beam etch (NBE), the like, or a combination thereof. The etching may be anisotropic.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as masks to pattern the fins 62 and the nanostructures 64, 66. In some embodiments, the mask (or other layer) may remain on the nanostructures 64, 66.

The fins 62 and the nanostructures 64, 66 may each have widths in a range of about 8 nm to about 40 nm. In the illustrated embodiment, the fins 62 and the nanostructures 64, 66 have substantially equal widths in the n-type region 50N and the p-type region 50P. In another embodiment, the fins 62 and the nanostructures 64, 66 in one region (e.g., the n-type region 50N) are wider or narrower than the fins 62 and the nanostructures 64, 66 in another region (e.g., the p-type region 50P).

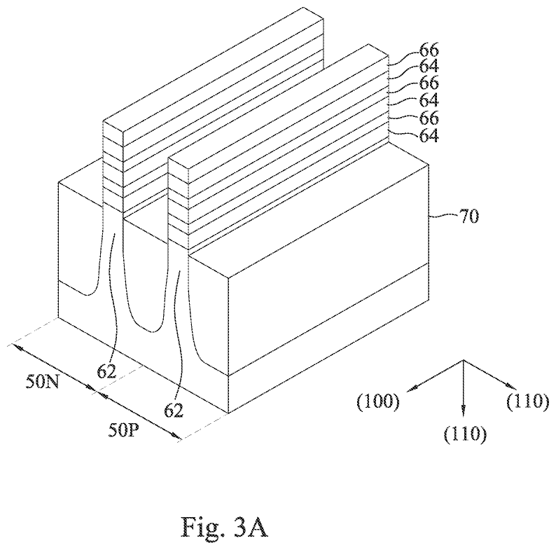

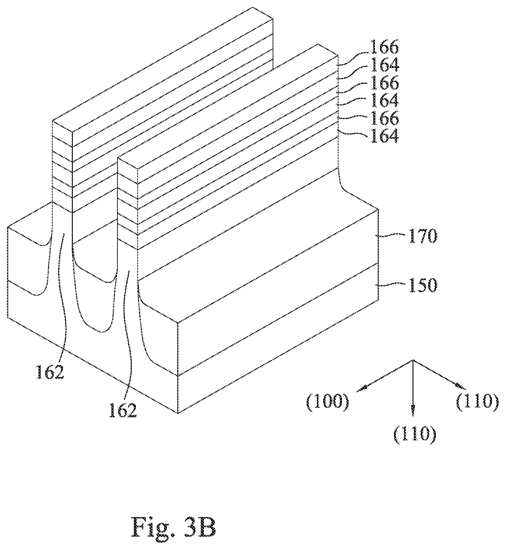

With reference to FIG. 3A, shallow trench isolation (STI) regions 70 are formed over the substrate 50 and between adjacent fins 62. The STI regions 70 are disposed around at least a portion of the fins 62 such that at least a portion of the nanostructures 64, 66 protrude from between adjacent STI regions 70. In the illustrated embodiment, the top surfaces of the STI regions 70 are coplanar (within process variations) with the top surfaces of the fins 62. In some embodiments, the top surfaces of the STI regions 70 are above or below the top surfaces of the fins 62. The STI regions 70 separate the features of adjacent devices.

The STI regions 70 may be formed by any suitable method. For example, an insulation material can be formed over the substrate 50 and the nanostructures 64, 66, and between adjacent fins 62. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In an embodiment, the insulation material is formed such that excess insulation material covers the nanostructures 64, 66. Although the STI regions 70 are each illustrated as a single layer, some embodiments may utilize multiple layers. For example, in some embodiments a liner (not separately illustrated) may first be formed along surfaces of the substrate 50, the fins 62, and the nanostructures 64, 66. Thereafter, a fill material, such as those previously described may be formed over the liner.

A removal process is then applied to the insulation material to remove excess insulation material over the nanostructures 64, 66. In some embodiments, a planarization process such as a chemical mechanical polish (CMP), an etch-back process, combinations thereof, or the like may be utilized. In embodiments in which a mask remains on the nanostructures 64, 66, the planarization process may expose the mask or remove the mask. After the planarization process, the top surfaces of the insulation material and the mask (if present) or the nanostructures 64, 66 are coplanar (within process variations). Accordingly, the top surfaces of the mask (if present) or the nanostructures 64, 66 are exposed through the insulation material. In the illustrated embodiment, no mask remains on the nanostructures 64, 66. The insulation material is then recessed to form the STI regions 70. The insulation material is recessed such that at least a portion of the nanostructures 64, 66 protrude from between adjacent portions of the insulation material. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The insulation material may be recessed using any acceptable etching process, such as one that is selective to the material of the insulation material (e.g., selectively etches the insulation material of the STI regions 70 at a faster rate than the materials of the fins 62 and the nanostructures 64, 66). For example, an oxide removal may be performed using dilute hydrofluoric (dHF) acid.

The process previously described is just one example of how the fins 62 and the nanostructures 64, 66 may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the nanostructures 64, 66, the fins 62, and/or the substrate 50. The wells may have a conductivity type opposite from a conductivity type of source/drain regions that will be subsequently formed in each of the n-type region 50N and the p-type region 50P. In some embodiments, a p-type well is formed in the n-type region 50N, and an n-type well is formed in the p-type region 50P. In some embodiments, a p-type well or an n-type well is formed in both the n-type region 50N and the p-type region 50P.

In embodiments with different well types, different implant steps for the n-type region 50N and the p-type region 50P may be achieved using mask (not separately illustrated) such as a photoresist. For example, a photoresist may be formed over the fins 62, the nanostructures 64, 66, and the STI regions 70 in the n-type region 50N. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in the range of about 10¹³ cm⁻³ to about 10¹⁴ cm⁻³. After the implant, the photoresist may be removed, such as by any acceptable ashing process.

Following or prior to the implanting of the p-type region 50P, a mask (not separately illustrated) such as a photoresist is formed over the fins 62, the nanostructures 64, 66, and the STI regions 70 in the p-type region 50P. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in the range of about 10¹³ cm⁻³ to about 10¹⁴ cm⁻³. After the implant, the photoresist may be removed, such as by any acceptable ashing process.

After the implants of the n-type region 50N and the p-type region 50P, an anneal may be performed to repair implant damage and to activate the p-type and/or n-type impurities that were implanted. In some embodiments where epitaxial structures are epitaxially grown for the fins 62 and/or the nanostructures 64, 66, the grown materials may be in situ doped during growth, which may obviate the implantations, although in situ and implantation doping may be used together.

While FIG. 3B shows another embodiment of the nano-FETs with STI regions having different cross-sectional profiles than the STI regions 70 in FIG. 3A. The STI regions 70 as shown in FIG. 3A may have a flat top surface substantially in a position level with a top surface of the fins 62. In some embodiments, the STI regions 70 may not be further recessed to have a concave-like top surface. As shown in FIG. 3B, the STI regions 170 are recessed, and thus have a concave-like top surface. In some embodiments, material and manufacturing method of a substrate 150, a fin 162, and nanostructures 164, 166 are substantially the same as those of the substrate 50, the fin 62, and the nanostructures 64, 66 as shown in FIG. 3A, and the related detailed descriptions may refer to the foregoing paragraphs, and are not described again herein.

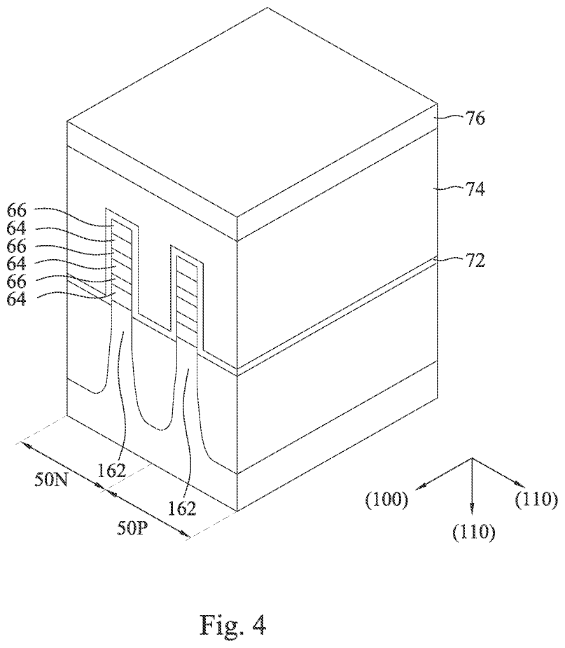

With reference to FIG. 4, a dummy dielectric layer 72 is formed on the fins 62 and the nanostructures 64, 66. The dummy dielectric layer 72 may be formed of a dielectric material such as silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer 74 may be formed of material(s) that have a high etching selectivity from the etching of insulation materials, e.g., the STI regions 70 and/or the dummy dielectric layer 72. The mask layer 76 may be formed of a dielectric material such as silicon nitride, silicon oxynitride, or the like. In this example, a single dummy gate layer 74 and a single mask layer 76 are formed across the n-type region 50N and the p-type region 50P. In the illustrated embodiment, the dummy dielectric layer 72 covers the fins 62, the nanostructures 64, 66, and the STI regions 70, such that the dummy dielectric layer 72 extends over the STI regions 70 and between the dummy gate layer 74 and the STI regions 70. In another embodiment, the dummy dielectric layer 72 covers only the fins 62 and the nanostructures 64, 66.

With reference to FIG. 5, the mask layer 76 is patterned using acceptable photolithography and etching techniques to form masks 86. The pattern of the masks 86 is then transferred to the dummy gate layer 74 by any acceptable etching technique to form dummy gates 84. The pattern of the masks 86 may optionally be further transferred to the dummy dielectric layer 72 by any acceptable etching technique to form dummy dielectrics 82. The dummy gates 84 cover portions of the nanostructures 64, 66 that will be exposed in subsequent processing to form channel regions. Specifically, the dummy gates 84 extend along the portions of the nanostructures 66 that will be patterned to form channel regions 68 (see FIG. 6A). The pattern of the masks 86 may be used to physically separate adjacent dummy gates 84. The dummy gates 84 may also have lengthwise directions substantially perpendicular (within process variations) to the lengthwise directions of the fins 62. The masks 86 can optionally be removed after patterning, such as by any acceptable etching technique.

FIGS. 6A, 7A, 8A, 9A, 10A, 11A, 12A, 13A, 14A, and 15A illustrate features in the n-type region 50N. FIGS. 6B, 7B, 8B, 9B, 10B, 11B, 12B, 13B, 14B, and 15B illustrate features in the p-type region 50P. FIGS. 6C, 7C, 8C, 9C, 10C, 11C, 12C, 13C, 14C, and 15C illustrate features in the n-type region 50N and the p-type region 50P.

With reference to FIGS. 6A, 6B, and 6C, gate spacers 90 are formed over the nanostructures 64, 66, on exposed sidewalls of the masks 86 (if present), the dummy gates 84, and the dummy dielectrics 82. The gate spacers 90 may be formed by conformally depositing one or more dielectric material(s) and subsequently etching the dielectric material(s). Acceptable dielectric materials may include silicon oxide, silicon nitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. In the illustrated embodiment, the gate spacers 90 each include multiple layers, e.g., a first spacer layer 90A and a second spacer layer 90B. In some embodiments, the first spacer layers 90A and the second spacer layers 90B are formed of silicon oxycarbonitride (e.g., SiOₓN_{y}C_{1-x-y}, where x and y are in the range of 0 to 1), with the first spacer layers 90A formed of a similar or a different composition of silicon oxycarbonitride than the second spacer layers 90B. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). As will be subsequently described in greater detail, the dielectric material(s), when etched, may also have portions left on the sidewalls of the fins 62 and/or the nanostructures 64, 66 (thus forming fin spacers 92, see FIGS. 9C and 9D). After etching, the fin spacers 92 and/or the gate spacers 90 can have straight sidewalls (as illustrated) or can have curved sidewalls (not separately illustrated).

Further, implants may be performed to form lightly doped source/drain (LDD) regions (not separately illustrated). In the embodiments with different device types, similar to the implants for the wells previously described, a mask (not separately illustrated) such as a photoresist may be formed over the n-type region 50N, while exposing the p-type region 50P, and appropriate type (e.g., p-type) impurities may be implanted into the fins 62 and/or the nanostructures 64, 66 exposed in the p-type region 50P. The mask may then be removed. Subsequently, a mask (not separately illustrated) such as a photoresist may be formed over the p-type region 50P while exposing the n-type region 50N, and appropriate type impurities (e.g., n-type) may be implanted into the fins 62 and/or the nanostructures 64, 66 exposed in the n-type region 50N. The mask may then be removed. The n-type impurities may be any of the n-type impurities previously described, and the p-type impurities may be any of the p-type impurities previously described. During the implanting, the channel regions 68 remain covered by the dummy gates 84, so that the channel regions 68 remain substantially free of the impurity implanted to form the LDD regions. The LDD regions may have a concentration of impurities in the range of about 10¹⁵ cm⁻³ to about 10¹⁹ cm⁻³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

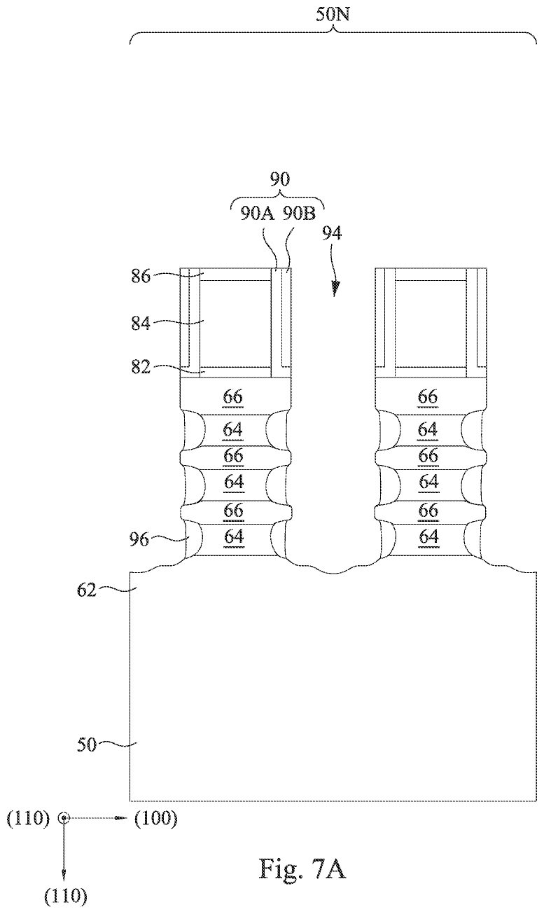

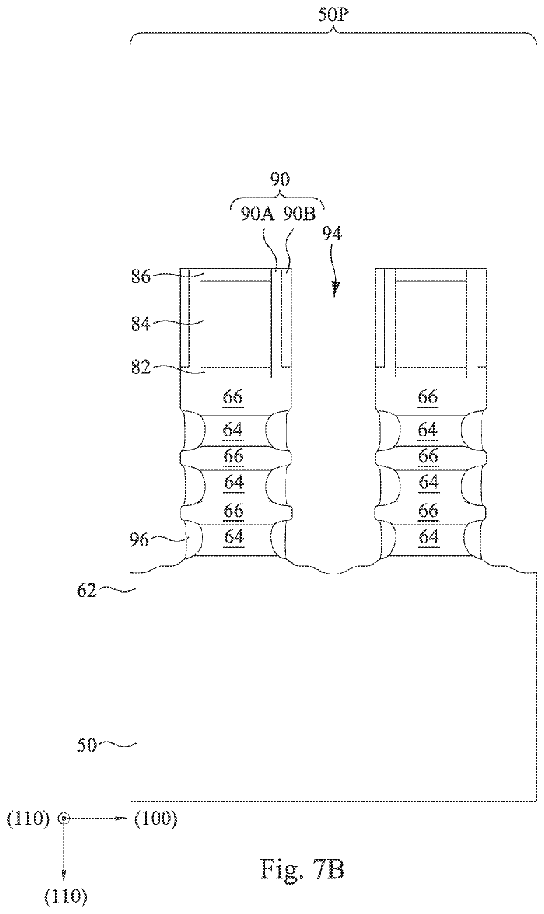

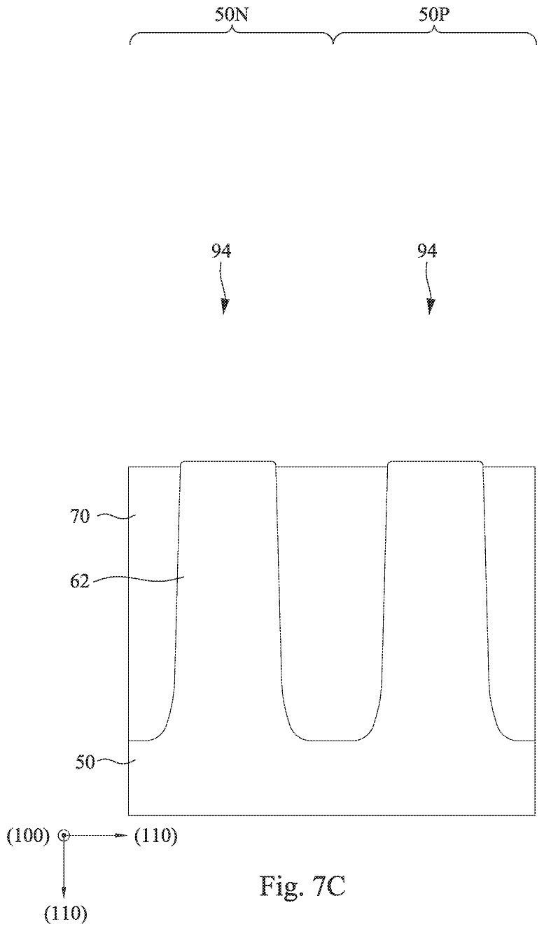

With reference to FIGS. 7A, 7B, and 7C, source/drain recesses 94 are formed in the nanostructures 64, 66. In the illustrated embodiment, the source/drain recesses 94 extend through the nanostructures 64, 66 and into the fins 62. The source/drain recesses 94 may also extend into the substrate 50. In various embodiments, the source/drain recesses 94 may extend to a top surface of the substrate 50 without etching the substrate the fins 62 may be etched such that bottom surfaces of the source/drain recesses 94 are disposed below the top surfaces of the STI regions 70; or the like. The source/drain recesses 94 may be formed by etching the nanostructures 64, 66 using an anisotropic etching processes, such as a RIE, a NBE, or the like. The gate spacers 90 and the dummy gates 84 collectively mask portions of the fins 62 and/or the nanostructures 64, 66 during the etching processes used to form the source/drain recesses 94. A single etch process may be used to etch each of the nanostructures 64, 66, or multiple etch processes may be used to etch the nanostructures 64, 66. Timed etch processes may be used to stop the etching of the source/drain recesses 94 after the source/drain recesses 94 reach a desired depth.

Optionally, inner spacers 96 are formed on the sidewalls of the remaining portions of the first nanostructures 64, e.g., those sidewalls exposed by the source/drain recesses 94. As will be subsequently described in greater detail, source/drain regions will be subsequently formed in the source/drain recesses 94, and the first nanostructures 64 will be subsequently replaced with corresponding gate structures. The inner spacers 96 act as isolation features between the subsequently formed source/drain regions and the subsequently formed gate structures. Further, the inner spacers 96 may be used to substantially prevent damage to the subsequently formed source/drain regions by subsequent etching processes, such as etching processes used to subsequently remove the first nanostructures 64.

As an example to form the inner spacers 96, the source/drain recesses 94 can be laterally expanded. Specifically, portions of the sidewalls of the first nanostructures 64 exposed by the source/drain recesses 94 may be recessed. Although sidewalls of the first nanostructures 64 are illustrated as being straight, the sidewalls may be concave or convex. The sidewalls may be recessed by any acceptable etching process, such as one that is selective to the material of the first nanostructures 64 (e.g., selectively etches the material of the first nanostructures 64 at a faster rate than the material of the second nanostructures 66). The etching may be isotropic. For example, when the second nanostructures 66 are formed of silicon and the first nanostructures 64 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94 and recess the sidewalls of the first nanostructures 64. The inner spacers 96 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 96 are illustrated as being flush with respect to the sidewalls of the gate spacers 90, the outer sidewalls of the inner spacers 96 may extend beyond or be recessed from the sidewalls of the gate spacers 90. In other words, the inner spacers 96 may partially fill, completely fill, or overfill the sidewall recesses. Moreover, although the sidewalls of the inner spacers 96 are illustrated as being straight, the sidewalls of the inner spacers 96 may be concave or convex.

With reference to FIGS. 8A, 8B, and 8C, epitaxial source/drain regions 42 are formed in the source/drain recesses 94 on the n-type region 50N (see FIGS. 8A and 8C), such that each dummy gate 84 (and corresponding channel regions 68) is disposed between respective adjacent pairs of the epitaxial source/drain regions 42. In some embodiments, the gate spacers 90 and the inner spacers 96 are used to separate the epitaxial source/drain regions 42 from, respectively, the dummy gates 84 and the first nanostructures 64 by an appropriate lateral distance so that the epitaxial source/drain regions 42 do not short out with subsequently formed gates of the resulting nano-FETs. A material of the epitaxial source/drain regions 42 may be selected to exert stress in the respective channel regions 68, thereby improving performance.

The epitaxial source/drain regions 42 in the n-type region 50N may be formed by masking the p-type region 50P with a mask 97. Then, the epitaxial source/drain regions 42 in the n-type region 50N are epitaxially grown in the source/drain recesses 94 in the n-type region 50N. The epitaxial source/drain regions 42 may include any acceptable material appropriate for n-type devices. For example, the epitaxial source/drain regions 42 in the n-type region 50N may include materials exerting a tensile strain on the channel regions 68, such as silicon, silicon carbide, phosphorous doped silicon carbide, silicon phosphide, or the like. The epitaxial source/drain regions 42 in the n-type region 50N may be referred to as “n-type source/drain regions.” The epitaxial source/drain regions 42, the nanostructures 64, 66, and/or the fins 62 may be implanted with n-type impurities to form source/drain regions, similar to the process previously described for forming LDD regions, followed by an anneal. The source/drain regions may have an impurity concentration in the range of about 10¹⁹ cm⁻³ to about 10²¹ cm⁻³. In some embodiments, the epitaxial source/drain regions 42 may be in situ doped during growth.

The (110) surface orientation of the substrate 50 is used to assist in formation of quadrilateral cross-sectional epitaxial source/drain regions 42. This is described in greater detail with reference to FIG. 8C, the orientation of the epitaxial source/drain regions 42 is dependent on the orientation of the second nanostructure 66. The orientation of the first and second nanostructures 64 and 66 are dependent on the orientation of the substrate 50. Therefore, a quadrilateral cross-sectional profile of the epitaxial source/drain regions 42 is formed due to the surface orientations of the substrate 50. In some embodiments, the quadrilateral cross-sectional profile can be interchangeably referred to as a square bar cross-sectional profile. As mentioned above, the substrate 50 is designed to have the (110) surface orientation. The second nanostructures 66 formed on the (110) surface orientation substrate 50 also can have (110) surface orientation due to the epitaxial growth behavior. A growth rate of the epitaxial source/drain region 42 is laterally confined by (110) surface, such that the epitaxial source/drain region 42 may have a minimal increment on the lateral dimension thereof, which in turn reduces the epitaxial source/drain region 42 to have the chance of merging with adjacent epitaxial source/drain region and increases a subsequent process window on the epitaxial source/drain region 42. The epitaxial source/drain region 42 is laterally confined by (110) surface to lower a growth rate variation thereof in a lengthwise direction the gate structure and to reduce an impact thereon due to a fin sidewall (FSW) variation, and thereby a yield of the device may be improved.

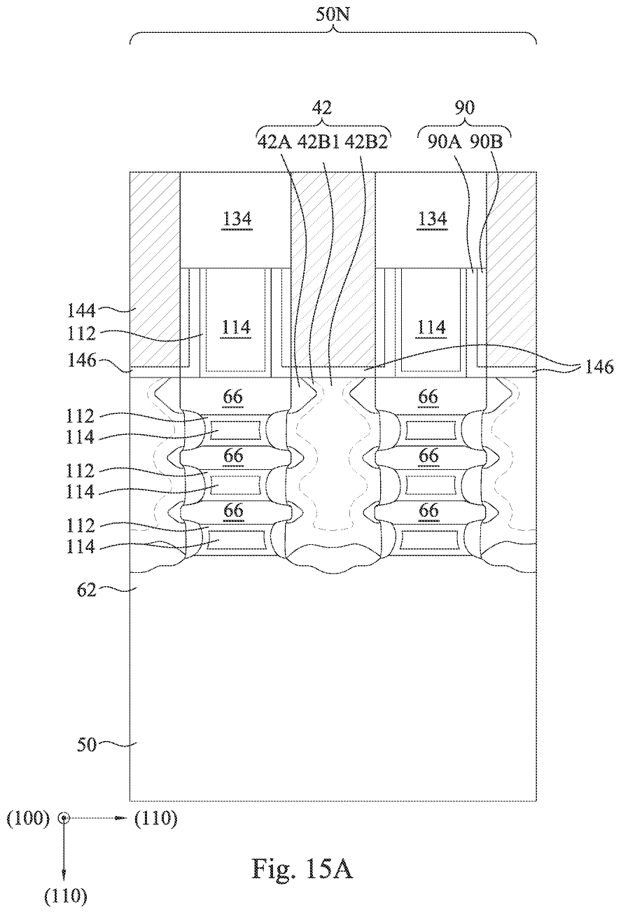

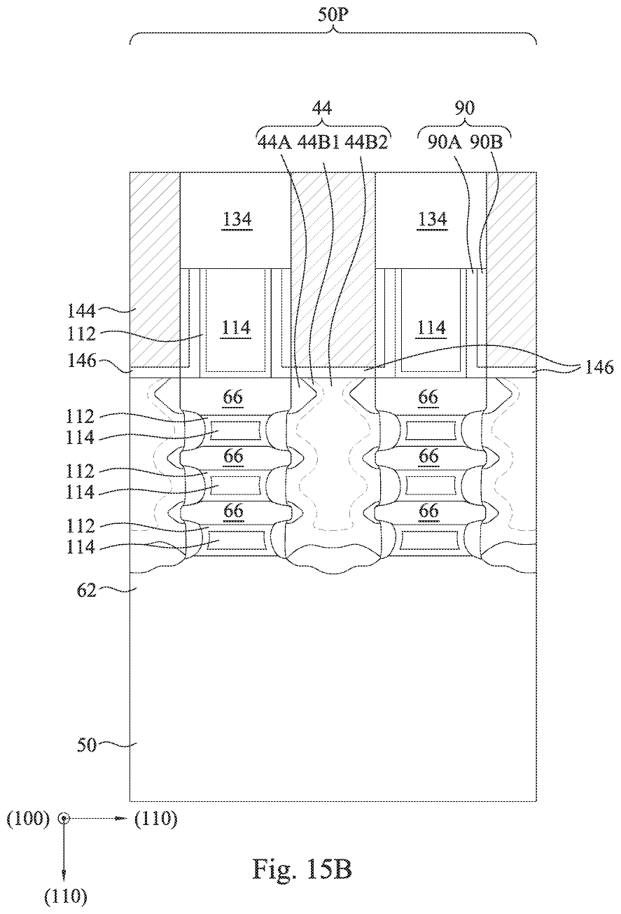

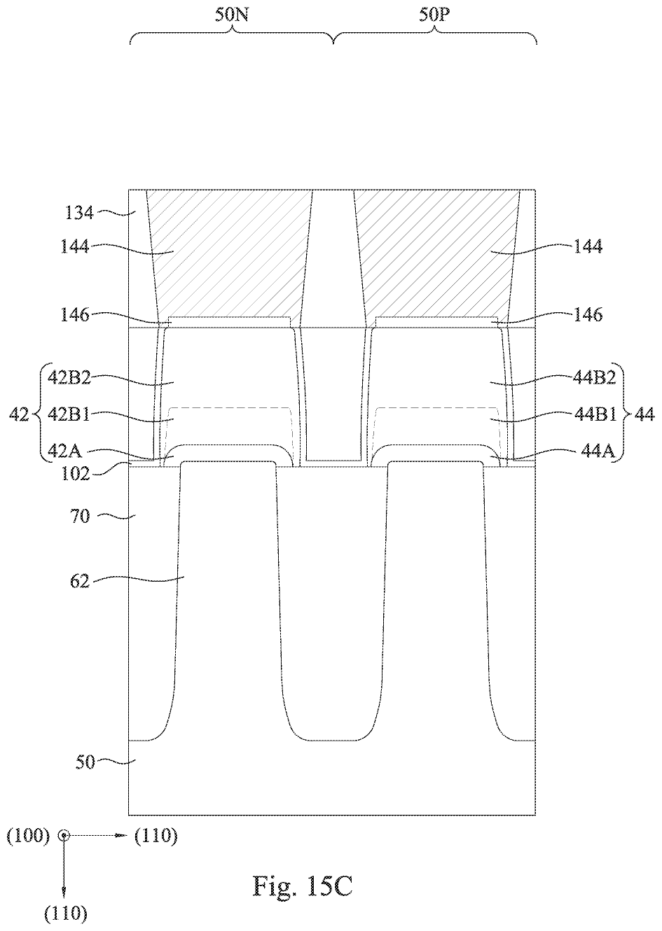

Therefore, the epitaxial source/drain regions 42 formed on the (110) surface orientation nanostructure 66 can grow along a vertical direction (e.g. Y-axis) and a horizontal direction (e.g. X-axis) resulting in the quadrilateral cross-sectional profile due to the epitaxial growth behavior. More specifically, when the substrate 50 has (110) surface orientation and the channel directly below the dummy gate 84 extends along the <100> directions, the sidewall of the epitaxial source/drain regions 42 can be grown along the <110> direction. The growth rate of the epitaxial source/drain regions 42 along the vertical direction is greater than that of the epitaxial source/drain regions 42 along the horizontal direction. In some embodiments, a ratio of vertical growth rate to the horizontal growth rate is in a range greater than about 2, such as about 2, 3, 4, 5, 6, 7, or 8. When the ratio is within the above-mentioned range, quadrilateral cross-sectional epitaxial source/drain regions 42 can be obtained. Therefore, due to silicon crystallographic properties, the (110) orientation epitaxial source/drain regions 42 formed on the channel extending along the <100> direction over the (110) surface orientation substrate 50 can have a quadrilateral cross-sectional profile to provide more contact area to contact the source/drain contact 144 (see FIG. 15C) and have a substantially same width at different heights, which in turn allows for achieving a larger metal contact area and a lesser epitaxial source/drain region. The larger metal contact area can improve resistance of the device, and the less epitaxial source/drain region can improve a source/drain region merge window and reduce capacity of the device, and thus the device performance may be improved.

As a result, the epitaxial source/drain regions 42 in the n-type region 50N may have surfaces upwardly raised from respective surfaces of the fins 62 and the nanostructures 64, 66, and may have vertical facets, and an upper surface of the epitaxial source/drain region 42 can be a horizontal facet which laterally between the vertical facets thereof. In some embodiments, adjacent epitaxial source/drain regions 42 remain separated after the epitaxy process is completed as illustrated by FIG. 9C. In some embodiments, the epitaxial source/drain regions 42 each has a width slightly decreasing as a distance from the substrate 50 increases. In some embodiments, a bottom portion of the epitaxial source/drain region 42 is wider than a middle portion of the epitaxial source/drain region 42. In some embodiments, a top surface of the epitaxial source/drain region 42 is in parallel with a bottom surface of the epitaxial source/drain region 42. In some embodiments, the STI region 70 has a flat top surface in a position level with a top end of the fin 62, and the epitaxial source/drain region 42 may have vertical sidewalls extending upwardly from the STI region 70. In some embodiments, the epitaxial source/drain regions 42 is higher than a topmost one of the nanostructures 66 in a range less than about 10 nm, such as 1, 2, 3, 4, 4.5, 5, 6, 7, 8, 9, or 10 nm. In some embodiments, the epitaxial source/drain regions 42 has a sidewall laterally extending beyond a sidewall of the fin 62 in a range less than about 12 nm, such as 5, 6, 7, 8, 9, 10, 11, or 12 nm. In some embodiments, a top surface 42t of the epitaxial source/drain region 42 can be flat and can be interchangeably referred to as a plateau. In some embodiments, the top surface 42t of the epitaxial source/drain region 42 may laterally extend beyond opposite sidewalls of the underlying fin 62.

The epitaxial source/drain regions 42 may include one or more semiconductor material layers. For example, the epitaxial source/drain regions 42 may each include a first semiconductor material layer 42A grown in the source/drain recesses 94, a second semiconductor material layer 42B1 grown on the first semiconductor material layer 42A, and a third semiconductor material layer 42B2 grown on the second semiconductor material layer 42B1. Any number of semiconductor material layers may be used for the epitaxial source/drain regions 42. In some embodiments, the first semiconductor material layer 42A can be interchangeably referred to as an epitaxy layer L1, the second semiconductor material layer 42B1 can be interchangeably referred to as an epitaxy layer L21, and the third semiconductor material layer 42B2 can be interchangeably referred to as an epitaxy layer L22 and with the epitaxy layer L21 collectively referred to as a layer L2. Each of the first semiconductor material layer 42A, the second semiconductor material layer 42B1, and the third semiconductor material layer 42B2 may be formed of different semiconductor materials and may be doped to different impurities.

The first semiconductor material layer 42A is deposited through an epitaxy process and may be performed using reduced pressure chemical vapor deposition (RPCVD), plasma enhanced chemical vapor deposition (PECVD), or the like. In some embodiments, the first semiconductor material layer 42A may be formed of or comprises SiAs. In some embodiments, the first semiconductor material layer 42A may be formed of or comprises SiP. In some embodiments, the first semiconductor material layer 42A may be formed of or comprise a SiAs layer and a SiP layer over the SiAs layer. In some embodiments, the process gas for depositing the first semiconductor material layer 42A may include a silicon-containing gas such as silane, disilane (Si₂H₆), dicholorosilane (H₂SiCl₂, DCS), or the like, and a dopant-containing process gas such as PH₃, AsH₃, or the like, depending on the desirable composition of first semiconductor material layer 42A. In some embodiments, the chamber pressure may be in the range between about 100 Torr and about 300 Torr, such as 100, 150, 200, 250, or 300 Torr. In some embodiments, the deposition process for forming the first semiconductor material layer 42A may be performed with a time duration in a range from about 10 seconds to about 350 seconds, such as 10, 14, 50, 100, 150, 200, 236, 250, or 300 seconds. In some embodiments, the deposition process for forming the first semiconductor material layer 42A may be performed with a deposition ratio in a range from about 0.1 nm/s to about 1 nm/s, such as 0.1, 0.2, 0.3, 0.4, 0.5, 0.6, 0.7, 0.8, 0.9, or 1 nm/s. In some embodiments, the first semiconductor material layer 42A may have a first doping concentration in the range between about 1×10²⁰/cm³ and about 1×10²¹/cm³ when P is incorporated. In some embodiments, the first semiconductor material layer 42A may also have a first doping concentration in the range between about 1×10²⁰/cm³ and about 1×10²¹/cm³ when As is incorporated.

In some embodiments, after the epitaxy process for depositing the first semiconductor material layer 42A, an etching (back) process is performed. The etching process is performed to achieve a selective deposition on semiconductor, but not on dielectric. In some embodiments, the etching-back is isotropic. The etching process may be performed using an etching gas such as HCl and a carrier gas(es) such as H₂ and/or N₂. The carrier gas(es) may be performed with a flow rate in the range between about 50 sccm and about 500 sccm. The preceding deposition process and the subsequent etching back are optimized so that first semiconductor material layer 42A has a desirable thickness. The deposition time and the etching time may be adjusted accordingly, for example, with the deposition process lasts for about 20 seconds and about 60 seconds, and the etching process lasts for about 5 seconds and about 20 seconds.

Subsequently, the second and third semiconductor material layers 42B1 and 42B2 are formed, which have different atomic percentages of elements. In some embodiments, instead of forming two semiconductor material layers, a single semiconductor material layer 42B with uniform atomic percentages of elements is formed. Accordingly, instead of performing an etching back process for each of the second, third semiconductor material layers 42B1 and 42B2, a single etching back process is performed after the epitaxy of semiconductor material layer 42B.

The second semiconductor material layer 42B1 is deposited through an epitaxy process and may be performed using RPCVD, PECVD, or the like. An n-type dopant is added into second semiconductor material layer 42B1. In the discussion of the second and third semiconductor material layers 42B1 and 42B2, phosphorous is discussed as an example of the n-type dopants, while other n-type dopants such as arsenic, antimony, or the like, or combinations thereof, may be used. For example, the first and second semiconductor material layers 42B1 and 42B2 may include silicon phosphorous. In some embodiments, the second and third semiconductor material layers 42B1 and 42B2 may be doped with different dopants than the first semiconductor material layer 42A. For example, the second and third semiconductor material layers 42B1 and 42B2 may be doped with phosphorous, and the first semiconductor material layer 42A may be doped with arsenic. In some embodiments, the second and third semiconductor material layers 42B1 and 42B2 may be doped with a same dopant as the first semiconductor material layer 42A. For example, the first, second, and third semiconductor material layers 42A, 42B1, and 42B2 may be doped with phosphorous or arsenic. In some embodiments, the second semiconductor material layer 42B1 may have a second doping concentration higher than the first doping concentration in the first semiconductor material layer 42A. For example, the second doping concentration in the second semiconductor material layer 42B1 may be in the range between about 8×10²⁰/cm³ and about 5×10²¹/cm³. The second doping concentration may be about one order or two orders higher than the first doping concentration in the first semiconductor material layer 42A.

In some embodiments, the process gas for depositing the second semiconductor material layer 42B1 may include a silicon-containing gas such as silane, disilane (Si₂H₆), dicholorosilane (H₂SiCl₂, DCS), or the like, and a dopant-containing process gas such as PH₃, AsH₃, or the like, depending on the desirable composition of the second semiconductor material layer 42B1. The flow rates of the process gases for forming the second semiconductor material layer 42B1 may be different from the flow rates of the corresponding process gases in the formation of first semiconductor material layer 42A. In some embodiments, if the process gases for forming the second semiconductor material layer 42B1 includes silane (SiH₄), and the silane may be introduced into the process chamber with a flow rate in a range from about 20 to about 80 sccm, such as 20, 30, 40, 50, 60, 70, or 80 sccm. In some embodiments, if the process gases for forming the second semiconductor material layer 42B1 includes dicholorosilane (H₂SiCl₂, DCS), and the dicholorosilane may be introduced into the process chamber with a flow rate in a range from about 130 to about 900 sccm, such as 130, 200, 300, 400, 500, 600, 700, 800, or 900 sccm. In some embodiments, the chamber pressure may be in a range from about 100 Torr to about 200 Torr, such as 100, 145, 150, or 200 Torr. In some embodiments, the deposition process for forming the second semiconductor material layer 42B1 may be performed with a deposition ratio in a range from about 0.4 nm/s to about 0.8 nm/s, such as 0.4, 0.5, 0.6, 0.61, 0.7, or 0.8 nm/s.

In some embodiments, after the epitaxy to deposit the second semiconductor material layer 42B1, an etching (back) process is performed. In some embodiments, the etching process is isotropic. In some embodiments, the etching process is performed using an etching gas such as HCl, and a carrier gas(es) such as H2 and/or N2. In some embodiments, the etching gas may be introduced into the process chamber with a flow rate in a range from about 1500 to about 2500 sccm, such as 1500, 1600, 1700, 1800, 1900, 2000, 2100, 2200, 2300, 2400, or 2500 sccm. In addition, a silicon-containing gas such as silane may be added in the etching gas. The addition of the silicon-containing gas results in a deposition effect, which occurs concurrently as the etching effect. The etching rate, however, is greater than the deposition rate, so that the net effect is the etching-back of second semiconductor material layer 42B1. The addition of the silicon-containing gas reduces the net etching rate, so that when the surface profile of second semiconductor material layer 42B1 is re-shaped, the thickness of second semiconductor material layer 42B1 is not reduced significantly. The deposition and the etching are optimized so that second semiconductor material layer 42B1 has a desirable thickness. In some embodiments, the etching process for forming the second semiconductor material layer 42B1 may be performed with an etching ratio in a range from about 0.2 nm/s to about 0.4 nm/s, such as 0.25, 0.3, 0.31, 0.35, or 0.4 nm/s.

In some embodiments, the forming of the second semiconductor material layer 42B1 is a cyclic process including at least one repetition (e.g., twice, three times, four times) of a deposition process and an etching process. For example, it may perform a deposition process followed by a an etching process, and repeats the deposition process and the etching process. In some embodiments, the deposition process for forming the second semiconductor material layer 42B1 may be performed with a time duration in a range from about 5 seconds to about 15 seconds, such as 5, 6, 7, 8, 9, 10, 11, 12, 13, 14, or 15 seconds. In some embodiments, the etching process for forming the second semiconductor material layer 42B1 may be performed with a time duration in a range from about 5 seconds to about 15 seconds, such as 5, 6, 7, 8, 9, 10, 11, 12, 13, 14, or 15 seconds. In some embodiments, the time duration of the etching process for forming the second semiconductor material layer 42B1 is longer then the time duration of the deposition process for forming the second semiconductor material layer 42B1. In some embodiments, the time duration for forming the second semiconductor material layer 42B1 is shorter than the time duration for forming the first semiconductor material layer 42A.

The third semiconductor material layer 42B2 is deposited through an epitaxy process and may be performed using RPCVD, PECVD, or the like. An n-type dopant is added into the third semiconductor material layer 42B2. In some embodiments, the third semiconductor material layer 42B2 may be doped with a same dopant as the second semiconductor material layer 42B1. For example, the second and third semiconductor material layers 42B1 and 42B2 may be doped with phosphorous or arsenic. In some embodiments, the third semiconductor material layer 42B2 may include silicon phosphorous. In some embodiments, the third semiconductor material layer 42B2 may have a third doping concentration higher than the second doping concentration in the second semiconductor material layer 42B1. Furthermore, third semiconductor material layer 42B2 has the highest doping concentration in the resulting epitaxial source/drain regions 42. For example, the third doping concentration in epitaxy layers 42B2 may be in the range between about 2×10²¹/cm³ and about 5×10²¹/cm³. The ratio of the third doping concentration to the second doping concentration of second semiconductor material layer 42B1 may be in the range between about 3 and about 6. The process gases for forming the third semiconductor material layer 42B2 may be similar to the process gases in the formation of second semiconductor material layer 42B1, except the flow rates are adjusted to achieve the desirable concentrations.

In some embodiments, the process gas for depositing the third semiconductor material layer 42B2 may include a silicon-containing gas such as silane, disilane (Si₂H₆), dicholorosilane (H₂SiCl₂, DCS), or the like, and a dopant-containing process gas such as PH₃, AsH₃, or the like, depending on the desirable composition of the second semiconductor material layer 42B1. The flow rates of the process gases for forming the third semiconductor material layer 42B2 may be different from the flow rates of the corresponding process gases in the formation of second semiconductor material layer 42B1. In some embodiments, if the dopant-containing process gas such as PH₃ for forming the third semiconductor material layer 42B2 includes phosphane (PH₃), and the phosphane may be introduced into the process chamber with a flow rate in a range from about 300 to about 500 sccm, such as 300, 350, 400, 410, 450, or 500 sccm. In some embodiments, the chamber pressure may be in the range between about 200 Torr and about 400 Torr, such as 200, 250, 300, 350, or 400 Torr. In some embodiments, the forming of the third semiconductor material layer 42B2 may be performed at a process temperature in a range from about 500 to about 1000 degree C., such as 500, 600, 700, 725, 800, 900, or 1000 degree C. In some embodiments, the deposition process for forming the third semiconductor material layer 42B2 may be performed with a deposition ratio in a range from about 1 nm/s to about 2 nm/s, such as 1, 1.2, 1.4, 1.44, 1.6, 1.8, or 2 nm/s.

In some embodiments. after the epitaxy process for depositing the third semiconductor material layer 42B2, an etching process is performed on the third semiconductor material layer 42B2 and results in the epitaxial source/drain regions 42 having a diamond shape top view as shown in FIG. 8F. In some embodiments, the third semiconductor material layer 42B2 may dominate a profile of the epitaxial source/drain regions 42. In some embodiments, the etching is isotropic. In some embodiments, the etching process is performed using an etching gas such as HCl and a carrier gas(es) such as H₂ and/or N₂. In addition, a silicon-containing gas such as silane may be added into the etching gas to deposit silicon. The etching process thus includes both of an etching effect and a deposition effect, with the net effect being etching. The addition of the silicon-containing gas reduces the etching rate, so that when the surface profile of third semiconductor material layer 42B2 is re-shaped, the thickness of third semiconductor material layer 42B2 is not reduced significantly. In some embodiments, the etching process for forming the third semiconductor material layer 42B2 may be performed with an etching ratio in a range from about 0.05 nm/s to about 0.2 nm/s, such as 0.05, 0.08, 0.1, 0.14, 0.18, or 0.2 nm/s.

In some embodiments, the forming of the third semiconductor material layer 42B2 is a cyclic process including at least one repetition (e.g., twice, three times, four times) of a deposition process and an etching process. For example, it may perform a deposition process followed by an etching process, and repeats the deposition process and the etching process. In some embodiments, the deposition process for forming the third semiconductor material layer 42B2 may be performed with a time duration in a range from about 7 seconds to about 17 seconds, such as 7, 8, 9, 10, 11, 12, 13, 14, 15, 16, or 17 seconds. In some embodiments, the etching process for forming the second semiconductor material layer 42B1 may be performed with a time duration in a range from about 15 seconds to about 25 seconds, such as 15, 16, 17, 18, 19, 20, 21, 22, 23, 24, or 25 seconds. In some embodiments, the time duration of the etching process for forming the third semiconductor material layer 42B2 is longer then the time duration of the deposition process for forming the third semiconductor material layer 42B2. In some embodiments, the time duration for forming the third semiconductor material layer 42B2 is longer than the time duration for forming the second semiconductor material layer 42B1, but shorter than the time duration for forming the first semiconductor material layer 42A.

In some embodiments, after the forming of the third semiconductor material layer 42B2, an etching process may be performed on the third semiconductor material layer 42B2 and results in the epitaxial source/drain regions 42 having a top view as shown in FIG. 8G. In some embodiments, the etching process is performed using an etching gas such as HCl and a carrier gas(es) such as H2 and/or N2. In addition, a germanium-containing gas such as germane (GeH₄), digermane (Ge₂H₆), or the like may be added into the etching gas. The etching process thus includes both of an etching effect and a deposition effect, with the net effect being etching. The addition of the germanium-containing gas reduces the etching rate, so that when the surface profile of third semiconductor material layer 42B2 is re-shaped, the thickness of third semiconductor material layer 42B2 is not reduced significantly. In some embodiments, the etching process may be performed with a time duration in a range from about 50 seconds to about 150 seconds, such as 50, 60, 70, 80, 90, 100, 110, 120, 130, 140, or 150 seconds. In some embodiments, the etching process on the third semiconductor material layer 42B2 may be performed with an etching ratio in a range from about 0.05 nm/s to about 0.2 nm/s, such as 0.05, 0.09, 0.12, 0.14, 0.18, or 0.2 nm/s.

While FIG. 8D shows some embodiments of an epitaxial source/drain region having different cross-sectional profile than the epitaxial source/drain region 42 shown in FIG. 8C. As shown in FIG. 8D, the epitaxial source/drain region 242 is formed with a longer process time than the epitaxial source/drain region 42 shown in FIG. 8C. Because the epitaxial source/drain region 242 is formed over a (110) surface orientation substrate 250, a growth rate of the epitaxial source/drain region 242 is laterally confined by (100) surface, such that the epitaxial source/drain region 242 may have a minimal increment on the lateral dimension thereof, which in turn reduces the epitaxial source/drain region 242 to have the chance of merging with adjacent epitaxial source/drain region and increases a subsequent process window on the epitaxial source/drain region 242. In addition, because the epitaxial source/drain region 242 is laterally confined by (110) surface to lower a growth rate variation thereof in a lengthwise direction the gate structure and to reduce an impact thereon due to a fin sidewall (FSW) variation, and thereby a yield of the device may be improved. For example, when the process time of the epitaxial source/drain region 242 is longer than 10% of the epitaxial source/drain region 42 as shown in FIG. 8C, the increment of the lateral dimension of the epitaxial source/drain region 242 may be in a range about 0.5 nm to about 1.2 nm relative to the epitaxial source/drain region 42, such as 0.5, 0.6, 0.7, 0.9, 1.0, 1.1, or 1.2 nm. In some embodiments, the epitaxial source/drain regions 242 has a sidewall laterally extending beyond a sidewall of the fin 262 in a range less than about 20 nm, such as 5, 10, 15, 17, 17.5, or 20 nm. In some embodiments, material and manufacturing method of a substrate 250, a fin 262, nanostructures 264, 266, semiconductor material layers 242A, 242B1, 242B2, STI regions 270, a mask 297 are substantially the same as those of the substrate 50, the fin 62, the semiconductor material layers 42A, 42B1, 42B2, the STI regions 70, and the mask 97 as shown in FIG. 8C, and the related detailed descriptions may refer to the foregoing paragraphs, and are not described again herein.

While FIG. 8E shows some embodiments of an epitaxial source/drain region having different cross-sectional profile than the epitaxial source/drain region 42 shown in FIG. 8C. As shown in FIG. 8E, the STI regions 370 are recessed such that a portion of the fin 362 protrudes from the STI regions 370. Therefore, if the epitaxial source/drain region 342 is formed to have a same vertical dimension as the epitaxial source/drain region 42 as shown in FIG. 8C, the epitaxial source/drain region 244 may have a longer process time than the epitaxial source/drain region 42. Because the epitaxial source/drain region 342 is formed over a (110) surface orientation substrate 350, a growth rate of the epitaxial source/drain region 342 is laterally confined by (110) surface, such that the epitaxial source/drain region 342 may have a minimal increment on the lateral dimension thereof, which in turn reduces the epitaxial source/drain region 342 to have the chance of merging with adjacent epitaxial source/drain region and increases a subsequent process window on the epitaxial source/drain region 342. In addition, because the epitaxial source/drain region 342 is laterally confined by (110) surface to lower a growth rate variation thereof in a lengthwise direction the gate structure and to reduce an impact thereon due to a fin sidewall (FSW) variation, and thereby a yield of the device may be improved. For example, when the STI regions 370 is lower than 1 nm relative to a top of the fin 362, the increment of the lateral dimension of the epitaxial source/drain region 342 may be in a range about 0.03 nm to about 0.08, such as 0.03, 0.04, 0.05, 0.06, 0.07, or 0.08 nm. In some embodiments, the epitaxial source/drain regions 342 has a sidewall laterally extending beyond a sidewall of the fin 362 in a range less than about 12 nm, such as 5, 6, 7, 8, 9, 10, 11, or 12 nm. In some embodiments, the STI region 370 have a concave top surface lower than a top end of the fin 62, and the epitaxial source/drain region 342 have straight sidewalls in parallel with sidewalls of the fin 62 and extending past the top end of the fin 62. In some embodiments, material and manufacturing method of a substrate 350, a fin 362, nanostructures 364, 366, semiconductor material layers 342A, 342B1, 342B2, STI regions 370, a mask 397 are substantially the same as those of the substrate 50, the fin 62, the semiconductor material layers 42A, 42B1, 42B2, the STI regions 70, the mask 97 as shown in FIG. 8C, and the related detailed descriptions may refer to the foregoing paragraphs, and are not described again herein.

With reference to FIGS. 9A, 9B, and 9C, epitaxial source/drain regions 44 are formed in the source/drain recesses 94 on the p-type region 50P (see FIGS. 9A and 9C), such that each dummy gate 84 (and corresponding channel regions 68) is disposed between respective adjacent pairs of the epitaxial source/drain regions 44. In some embodiments, the gate spacers 90 and the inner spacers 96 are used to separate the epitaxial source/drain regions 44 from, respectively, the dummy gates 84 and the first nanostructures 64 by an appropriate lateral distance so that the epitaxial source/drain regions 44 do not short out with subsequently formed gates of the resulting nano-FETs. A material of the epitaxial source/drain regions 44 may be selected to exert stress in the respective channel regions 68, thereby improving performance.

The epitaxial source/drain regions 44 in the p-type region 50P may be formed by masking the n-type region 50N with a mask 98. Then, the epitaxial source/drain regions 44 in the p-type region 50P are epitaxially grown in the source/drain recesses 94 in the p-type region 50P. The epitaxial source/drain regions 44 may include any acceptable material appropriate for p-type devices. For example, the epitaxial source/drain regions 44 in the p-type region 50P may include materials exerting a compressive strain on the channel regions 68, such as silicon germanium, boron doped silicon germanium, germanium, germanium tin, or the like. The epitaxial source/drain regions 44 in the p-type region 50P may be referred to as “p-type source/drain regions.” The epitaxial source/drain regions 44, the nanostructures 64, 66, and/or the fins 62 may be implanted with p-type impurities to form source/drain regions, similar to the process previously described for forming LDD regions, followed by an anneal. The source/drain regions may have an impurity concentration in the range of about 10¹⁹ cm⁻³ to about 10²¹ cm⁻³. In some embodiments, the epitaxial source/drain regions 44 may be in situ doped during growth. In the discussion of the first, second, and third semiconductor material layers 44A, 44B1, and 44B2, boron is discussed as an example of the p-type dopants, but the present disclosure is not limited thereto.

The (110) surface orientation of the substrate 50 is used to assist in formation of quadrilateral cross-sectional epitaxial source/drain regions 44. This is described in greater detail with reference to FIG. 9C, the orientation of the epitaxial source/drain regions 44 is dependent on the orientation of the second nanostructure 66. The orientation of the first and second nanostructures 64 and 66 are dependent on the orientation of the substrate 50. Therefore, a quadrilateral cross-sectional profile of the epitaxial source/drain regions 44 is formed due to the surface orientations of the substrate 50. As mentioned above, the substrate 50 is designed to have the (110) surface orientation. The second nanostructures 66 formed on the (110) surface orientation substrate 50 also can have (110) surface orientation due to the epitaxial growth behavior. The epitaxial source/drain regions 44 formed on the (110) surface orientation nanostructure 66 can grow along a vertical direction (e.g. Y-axis) and a horizontal direction (e.g. X-axis) resulting in the quadrilateral cross-sectional profile due to the epitaxial growth behavior. More specifically, when the substrate 50 has (110) surface orientation and the channel directly below the dummy gate 84 extends along the <100> direction, the sidewall of the epitaxial source/drain regions 44 can be grown along the <110> direction. The growth rate of the epitaxial source/drain regions 44 along the vertical direction is greater than that of the epitaxial source/drain regions 44 along the horizontal direction. In some embodiments, a ratio of vertical growth rate to the horizontal growth rate is in a range greater than about 2, such as about 2, 3, 4, 5, 6, 7, or 8. When the ratio is within the above-mentioned range, quadrilateral cross-sectional epitaxial source/drain regions 44 can be obtained. Therefore, due to silicon crystallographic properties, the (110) orientation epitaxial source/drain regions 44 formed on the channel extending along the <100> direction over the (110) surface orientation substrate 50 can have a quadrilateral cross-sectional profile to provide more contact area to contact the source/drain contact 144 (see FIG. 15C) and have a substantially same width at different heights, which in turn allows for achieving a larger metal contact area and a lesser epitaxial source/drain region. The larger metal contact area can improve resistance of the device, and the less epitaxial source/drain region can improve a source/drain region merge window and reduce capacity of the device, and thus the device performance may be improved.

As a result, the epitaxial source/drain regions 44 in the p-type region 50P may have surfaces upwardly raised from respective surfaces of the fins 62 and the nanostructures 64, 66, and may have vertical facets, and an upper surface of the epitaxial source/drain region 99 can be a horizontal facet which laterally between the vertical facets thereof. In some embodiments, adjacent epitaxial source/drain regions 44 remain separated after the epitaxy process is completed as illustrated by FIG. 9C. In some embodiments, the epitaxial source/drain regions 44 each has a width slightly decreasing as a distance from the substrate 50 increases. In some embodiments, a bottom portion of the epitaxial source/drain region 44 is wider than a middle portion of the epitaxial source/drain region 44. In some embodiments, a top surface of the epitaxial source/drain region 44 is in parallel with a bottom surface of the epitaxial source/drain region 44. In some embodiments, the STI region 70 has a flat top surface in a position level with a top end of the fin 62, and the epitaxial source/drain region 44 may have vertical sidewalls extending upwardly from the STI region 70. In some embodiments, the epitaxial source/drain regions 44 is higher than a topmost one of the nanostructures 66 in a range less than about 10 nm, such as 1, 2, 3, 4, 4.5, 5, 6, 7, 8, 9, or 10 nm. In some embodiments, the epitaxial source/drain regions 42 has a sidewall laterally extending beyond a sidewall of the fin 62 in a range less than about 12 nm, such as 5, 6, 7, 8, 9, 10, 11, or 12 nm. In some embodiments, a top surface 44t of the epitaxial source/drain region 44 can be flat and can be interchangeably referred to as a plateau. In some embodiments, the top surface 44t of the epitaxial source/drain region 44 may laterally extend beyond opposite sidewalls of the underlying fin 62.

The epitaxial source/drain regions 44 may include one or more semiconductor material layers. For example, the epitaxial source/drain regions 44 may each include a first semiconductor material layer 44A grown in the source/drain recesses 94, a second semiconductor material layer 44B1 grown on the first semiconductor material layer 44A, and a third semiconductor material layer 44B2 grown on the second semiconductor material layer 44B1. Any number of semiconductor material layers may be used for the epitaxial source/drain regions 44. Each of the first semiconductor material layer 44A, the second semiconductor material layer 44B1, and the third semiconductor material layer 44B2 may be formed of different semiconductor materials and may be doped to different impurities.

In some embodiments, the boron concentration in the first semiconductor material layer 44A may be in the range from about 1E20/cm³ and about 6E20/cm³. The boron concentration in the second semiconductor material layer 44B1 may be is in a range from about 6E20/cm³ to about 3E21/cm³. The boron concentration in the third semiconductor material layer 44B2 may be is in a range from about 1E21/cm³ to about 8E21/cm³. In some embodiments, the first semiconductor material layer 44A may have a lesser doping concentration than the second semiconductor material layer 44B1, and the third semiconductor material layer 44B2 may have a greater doping concentration than the second semiconductor material layer 44B2. In some embodiments, the germanium atomic percentage range in the first semiconductor material layer 44A may be in a range from about 15% to about 40%. In some embodiments, the germanium atomic percentage range in the second semiconductor material layer 44B1 may be in a range from about 40% to about 60%. In some embodiments, the germanium atomic percentage range in the third semiconductor material layer 44B2 may be in a range from about 45% to about 55%.

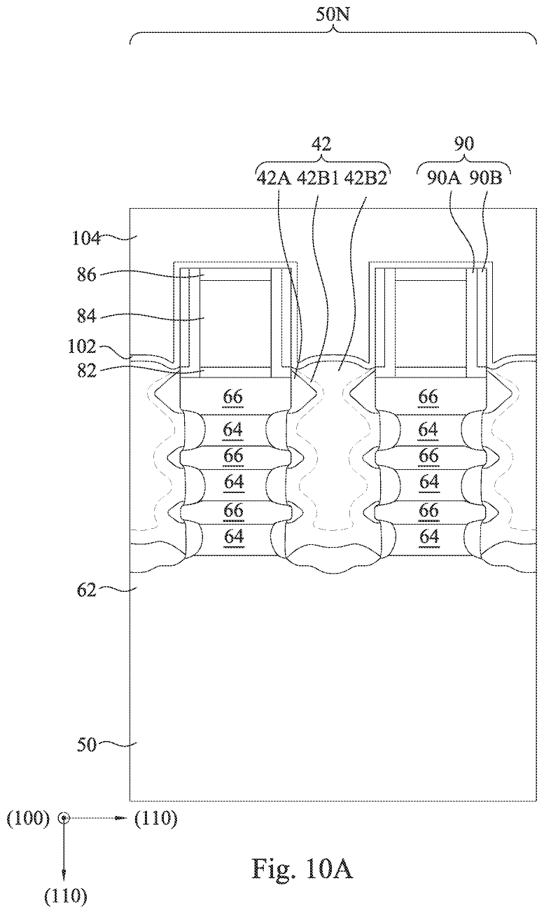

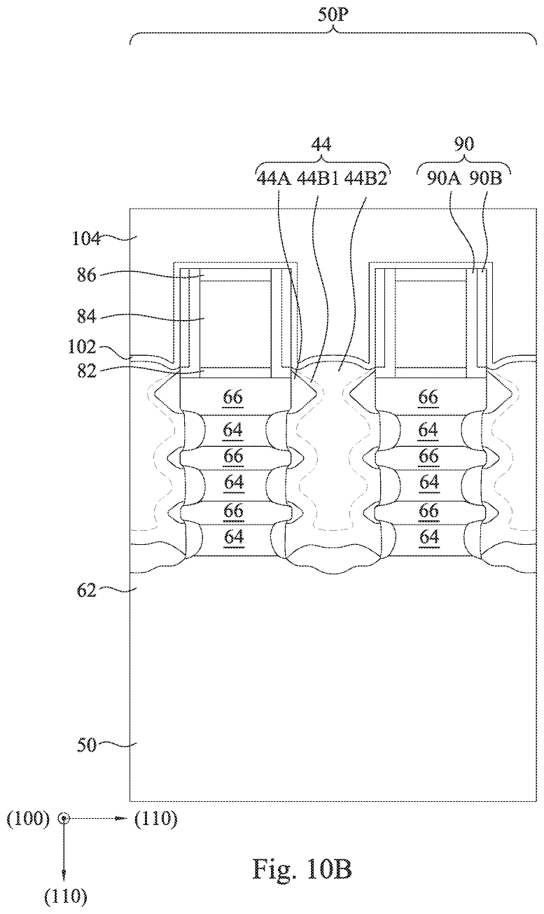

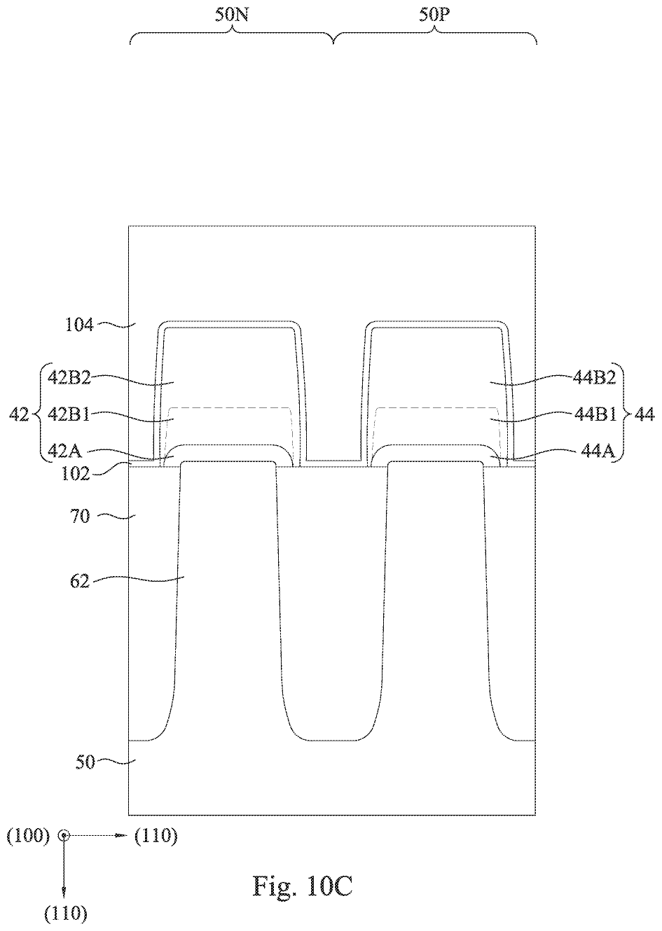

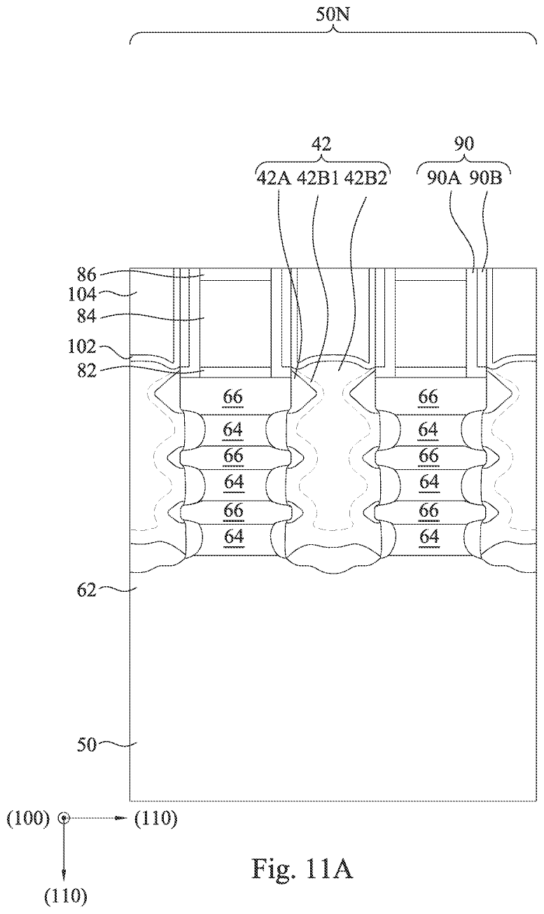

With reference to FIGS. 10A, 10B, and 10C, a first inter-layer dielectric (ILD) 104 is deposited over the epitaxial source/drain regions 42 and 44, the gate spacers 90, the masks 86 (if present) or the dummy gates 84. The first ILD 104 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 102 is formed between the first ILD 104 and the epitaxial source/drain regions 42 and 44, the gate spacers 90, and the masks 86 (if present) or the dummy gates 84. The CESL 102 may be formed of a dielectric material, such as silicon nitride, silicon oxide, silicon oxynitride, or the like, having a high etching selectivity from the etching of the first ILD 104. The CESL 102 may be formed by an any suitable method, such as CVD, ALD, or the like.

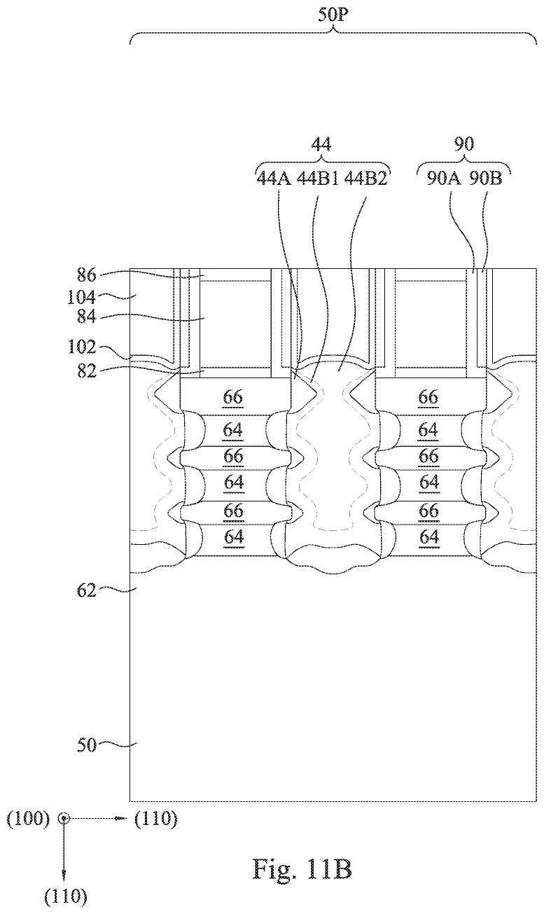

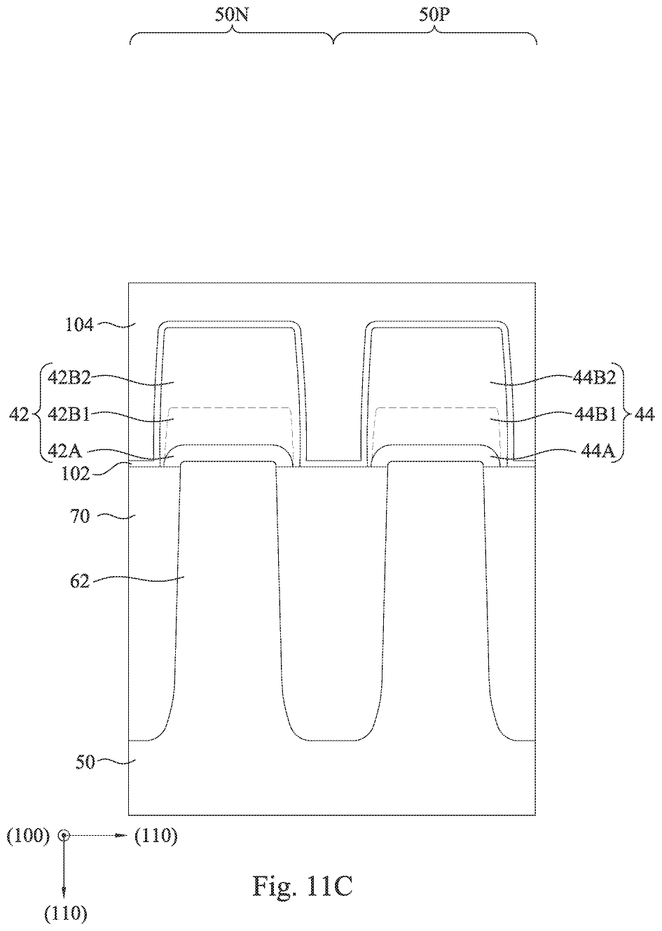

With reference to FIGS. 11A, 11B, and 11C, a removal process is performed to level the top surfaces of the first ILD 104 with the top surfaces of the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, the top surfaces of the gate spacers 90, the first ILD 104, the CESL 102, and the masks 86 (if present) or the dummy gates 84 are coplanar (within process variations). Accordingly, the top surfaces of the masks 86 (if present) or the dummy gates 84 are exposed through the first ILD 104. In the illustrated embodiment, the masks 86 remain, and the planarization process levels the top surfaces of the first ILD 104 with the top surfaces of the masks 86.

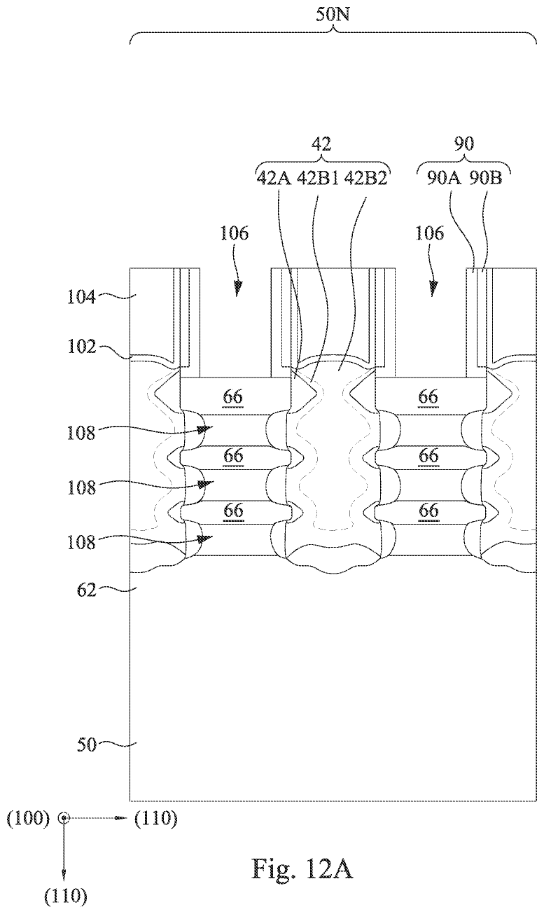

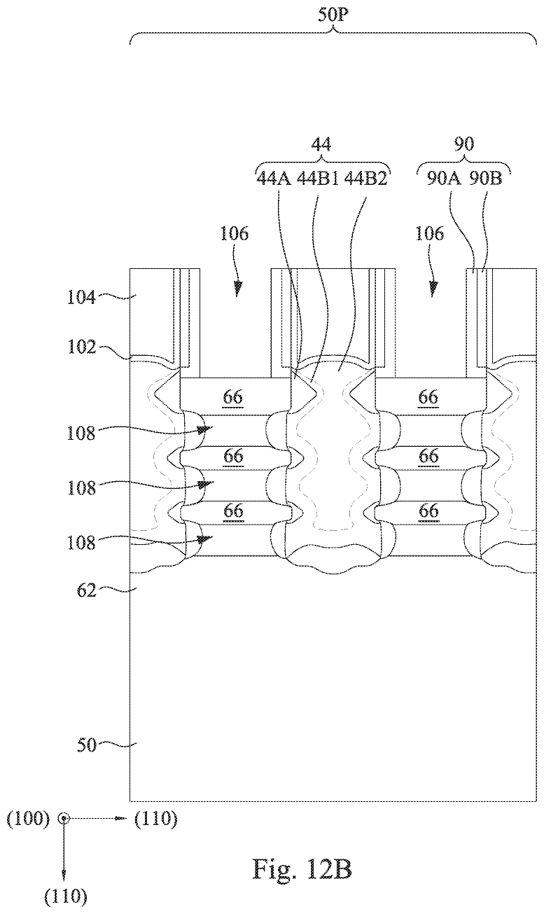

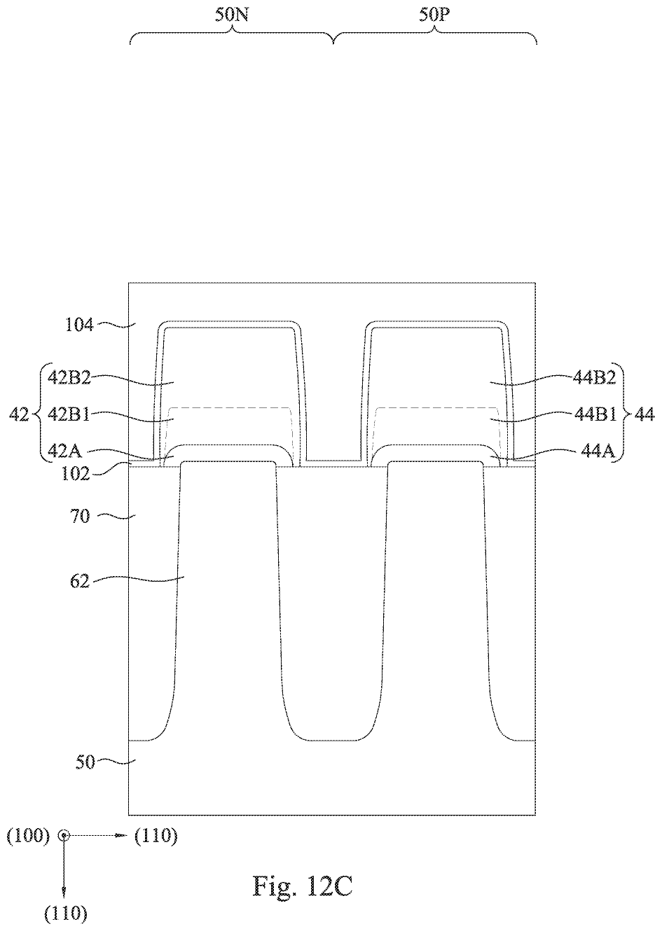

With reference to FIGS. 12A, 12B, and 12C, the masks 86 (if present) and the dummy gates 84 are removed in an etching process, so that recesses 106 are formed. Portions of the dummy dielectrics 82 in the recesses 106 are also removed. In some embodiments, the dummy gates 84 are removed by an anisotropic dry etch process. For example, the etching process may include a dry etch process using reaction gas(es) that selectively etch the dummy gates 84 at a faster rate than the first ILD 104 or the gate spacers 90. During the removal, the dummy dielectrics 82 may be used as etch stop layers when the dummy gates 84 are etched. The dummy dielectrics 82 are then removed. Each recess 106 exposes and/or overlies portions of the channel regions 68. Portions of the second nanostructures 66 which act as the channel regions 68 are disposed between adjacent pairs of the epitaxial source/drain regions 42 and 44.

The remaining portions of the first nanostructures 64 are then removed to expand the recesses 106, such that openings 108 are formed in regions between the second nanostructures 66. The remaining portions of the first nanostructures 64 can be removed by any acceptable etching process that selectively etches the material of the first nanostructures 64 at a faster rate than the material of the second nanostructures 66. The etching may be isotropic. For example, when the first nanostructures 64 are formed of silicon germanium and the second nanostructures 66 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second nanostructures 66.

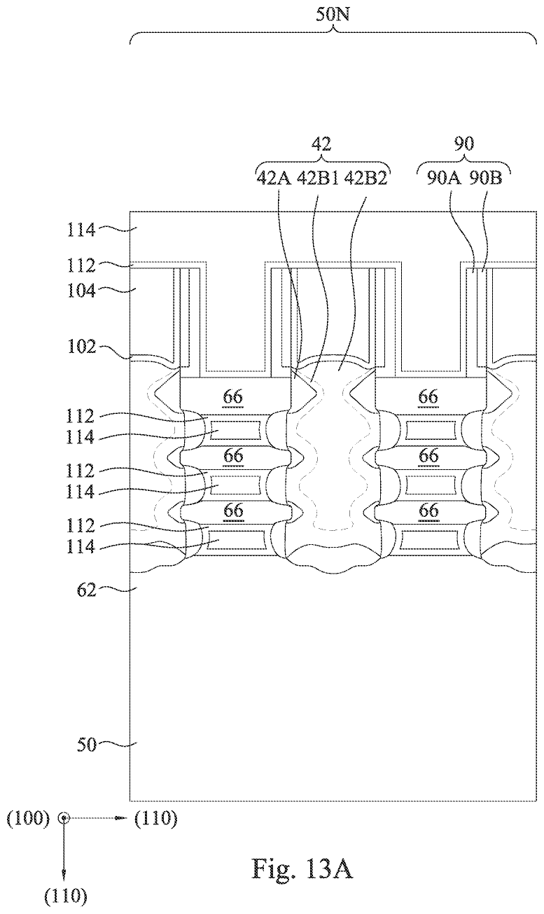

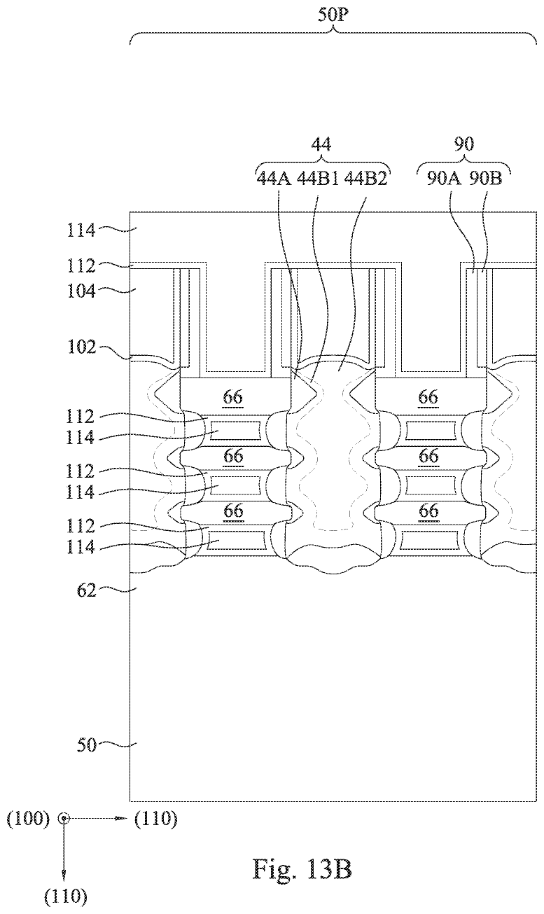

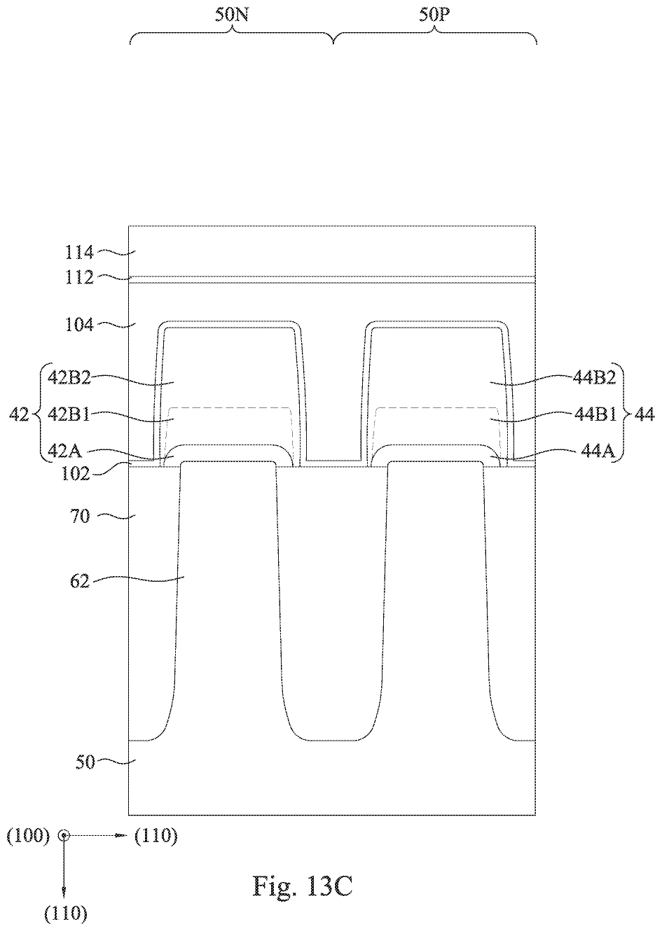

With reference to FIGS. 13A, 13B, and 13C, a gate dielectric layer 112 is formed in the recesses 106. A gate electrode layer 114 is formed on the gate dielectric layer 112. The gate dielectric layer 112 and the gate electrode layer 114 are layers for replacement gates, and each wrap around all (e.g., four) sides of the second nanostructures 66. The gate dielectric layer 112 is disposed on the sidewalls and/or the top surfaces of the fins 62; on the top surfaces, the sidewalls, and the bottom surfaces of the second nanostructures 66; and on the sidewalls of the gate spacers 90. The gate dielectric layer 112 may also be formed on the top surfaces of the first ILD 104 and the gate spacers 90. The gate dielectric layer 112 may include an oxide such as silicon oxide or a metal oxide, a silicate such as a metal silicate, combinations thereof, multi-layers thereof, or the like. The gate dielectric layer 112 may include a dielectric material having a k-value greater than about 7.0, such as a metal oxide or a silicate of hafnium, aluminum, zirconium, lanthanum, manganese, barium, titanium, lead, and combinations thereof. Although a single-layered gate dielectric layer 112 is illustrated in FIGS. 13A and 13B, the gate dielectric layer 112 may include any number of interfacial layers and any number of main layers. The gate electrode layer 114 may include a metal-containing material such as titanium nitride, titanium oxide, tungsten, cobalt, ruthenium, aluminum, combinations thereof, multi-layers thereof, or the like. Although a single-layered gate electrode layer 114 is illustrated in FIGS. 13A and 13B, the gate electrode layer 114 may include any number of work function tuning layers, any number of barrier layers, any number of glue layers, and a fill material.

The formation of the gate dielectric layers 112 in the n-type region 50N and the p-type region 50P may occur simultaneously such that the gate dielectric layers 112 in each region are formed of the same materials, and the formation of the gate electrode layers 114 may occur simultaneously such that the gate electrode layers 114 in each region are formed of the same materials. In some embodiments, the gate dielectric layers 112 in each region may be formed by distinct processes, such that the gate dielectric layers 112 may be different materials and/or have a different number of layers, and/or the gate electrode layers 114 in each region may be formed by distinct processes, such that the gate electrode layers 114 may be different materials and/or have a different number of layers. Various masking steps may be used to mask and expose appropriate regions when using distinct processes. In some embodiments, at least portions of the gate electrode layers 114 in the n-type region 50N and the gate electrode layers 114 in the p-type region 50P are formed separately.

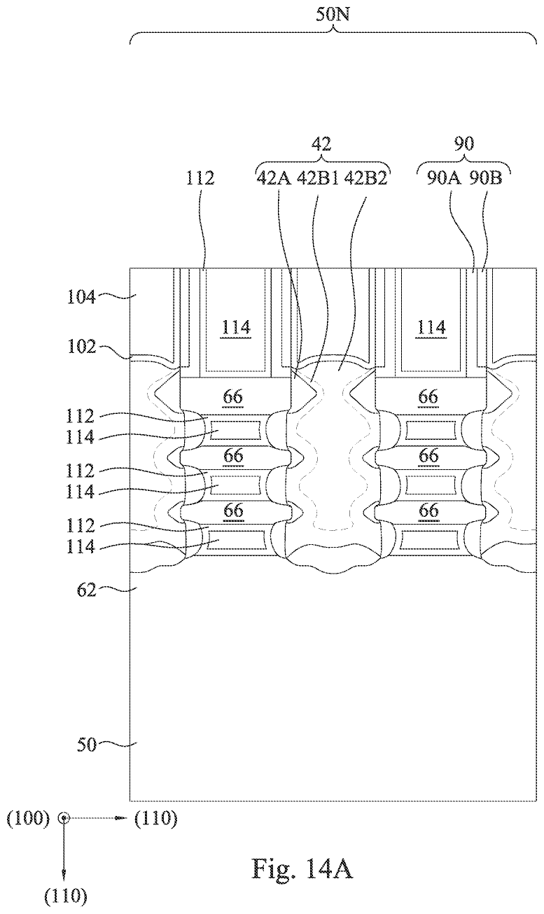

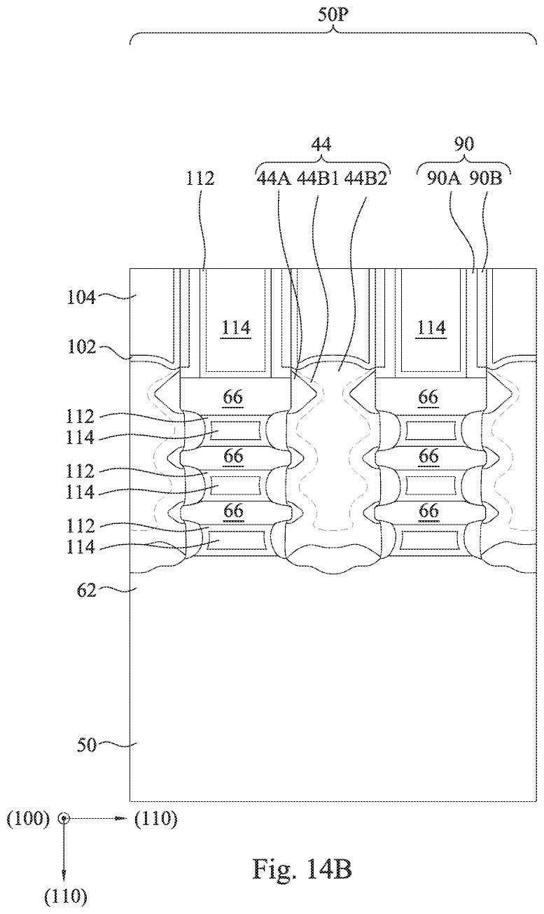

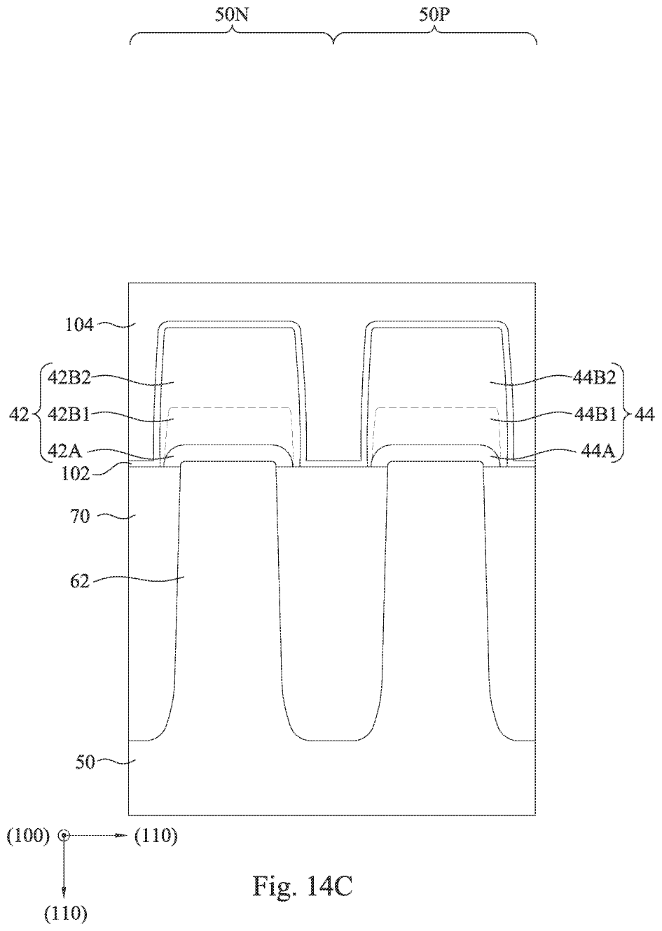

With reference to FIGS. 14A, 14B, and 14C, a removal process is performed to remove the excess portions of the materials of the gate dielectric layer 112 and the gate electrode layer 114, which excess portions are over the top surfaces of the first ILD 104 and the gate spacers 90, thereby forming gate dielectrics 122 and gate electrodes 124. In some embodiments, a planarization process such as a chemical mechanical polish (CMP), an etch-back process, combinations thereof, or the like may be utilized. The gate dielectric layer 112, when planarized, has portions left in the recesses 106 (thus forming the gate dielectrics 122). The gate electrode layer 114, when planarized, has portions left in the recesses 106 (thus forming the gate electrodes 124). The top surfaces of the gate spacers 90, the CESL 102, the first ILD 104, the gate dielectrics 122, and the gate electrodes 124 are coplanar (within process variations). The gate dielectrics 122 and the gate electrodes 124 form replacement gates of the resulting nano-FETs. Each respective pair of a gate dielectric 122 and a gate electrode 124 may be collectively referred to as a “gate structure.” The gate structures each extend along top surfaces, sidewalls, and bottom surfaces of a channel region 68 of the second nanostructures 66.

With reference to FIGS. 15A, 15B, and 15C, a second ILD 134 is deposited over the gate spacers 90, the CESL 102, the first ILD 104, the gate dielectrics 122, and the gate electrodes 124. In some embodiments, the second ILD 134 is a flowable film formed by a flowable CVD method. In some embodiments, the second ILD 134 is formed of a dielectric material such as silicon nitride, silicon oxide, silicon oxynitride PSG, BSG, BPSG, USG, or the like, which may be deposited by any suitable method, such as CVD, PECVD, or the like.

Source/drain contacts 144 are formed to contact the epitaxial source/drain regions 42 and 44. The source/drain contacts 144 are physically and electrically coupled to the epitaxial source/drain regions 42 and 44. In some embodiments, a lateral interface between the epitaxial source/drain regions 42 and 44 and the source/drain contacts 144 my be in a range from about 50 nm to about 70 nm, such as 50, 52, 54, 56, 58, 60, 62, 64, 66, 68, or 70 nm. As shown in FIG. 15C, a maximal lateral dimension of the epitaxial source/drain region 42 or 44 may be less than a maximal lateral dimension of the source/drain contact 144. In some embodiments, a sidewall of the epitaxial source/drain region 42 or 44 is steeper than a sidewall of the source/drain contact 144. In some embodiments, a sidewall of the metal contact 144 encloses the epitaxial source/drain region 42 or 44.

As an example to form the source/drain contacts 144, openings for the source/drain contacts 144 are formed through the second ILD 134, the first ILD 104, and the CESL 102. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 134. The remaining liner and conductive material form the source/drain contacts 144 in the openings. The source/drain contacts 144 may be formed in distinct processes, or may be formed in the same process. Although shown as being formed in the same cross-sections, it should be appreciated that each of the gate contacts 142 and the source/drain contacts 144 may be formed in different cross-sections, which may avoid shorting of the contacts.

Optionally, metal-semiconductor alloy regions 146 are formed at the interfaces between the epitaxial source/drain regions 42 and 44 and the source/drain contacts 144. The metal-semiconductor alloy regions 146 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 146 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the epitaxial source/drain regions 42 and 44 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 146. The material(s) of the source/drain contacts 144 can then be formed on the metal-semiconductor alloy regions 146.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an epitaxial source/drain region formed on a <110> channel over a (110) orientation substrate, and thus the epitaxial source/drain region can have a square bar cross-sectional profile to provide more contact area to contact an overlying source/drain contact and have a same width at different heights thereon, which in turn allows for achieving a larger metal contact area and a less epitaxial source/drain region. The larger metal contact area can improve resistance of the device, and the less epitaxial source/drain region can improve a source/drain region merge window and reduce capacity of the device, and thus the device performance may be improved.

In some embodiments, a method includes forming a channel region above a (110)-orientated substrate and having a length extending in a <100> direction; epitaxial growing a plurality of source/drain regions on either side the channel region; forming a gate structure surrounding the channel region; forming a plurality of source/drain contacts on the source/drain regions. In some embodiments, the source/drain regions each has a quadrilateral profile from a cross sectional view taken along a lengthwise direction of the gate structure. In some embodiments, a bottom portion of one of the source/drain regions is wider than a middle portion of the one of the source/drain regions from a cross sectional view taken along a lengthwise direction of the gate structure. In some embodiments, the source/drain regions each has a width decreasing as a distance from the (110)-orientated substrate increases from a cross sectional view taken along a lengthwise direction of the gate structure. In some embodiments, a top surface of one of the source/drain regions is in parallel with a bottom surface of the one of the source/drain regions. In some embodiments, a maximal lateral dimension of one of the source/drain regions is less than a maximal lateral dimension of one of the source/drain contacts from a cross sectional view taken along a lengthwise direction of the gate structure. In some embodiments, a sidewall of one of the source/drain regions is steeper than a sidewall of one of the source/drain contacts from a cross sectional view taken along a lengthwise direction of the gate structure. In some embodiments, epitaxial growing the source/drain regions exhibits a growth behavior on a (100)-orientation. In some embodiments, each of the source/drain regions comprise a first layer and a second layer over the first layer, the first layer comprises a first conductive type dopant, and the second layer comprises a second conductive type dopant different than the first conductive type dopant. In some embodiments, the first conductive type dopant is arsenic, and the second conductive type dopant is phosphorus.

In some embodiments, a method includes forming a multi-layer stack including alternating a plurality of channel layers and a plurality of sacrificial layers stacked in a vertical direction on a fin structure over a substrate having a (110) surface orientation; forming a shallow trench isolation (STI) structure laterally surrounding the fin structure; forming a plurality of epitaxial structures on either side of each of the channel layers, wherein the epitaxial structures each has a quadrilateral profile from a cross sectional view taken along a direction perpendicular to a lengthwise direction of the fin structure; replacing the sacrificial layers with a gate structure. In some embodiments, the channel layers each has a length extending along a <100> direction on the (110) surface orientation. In some embodiments, the STI structure has a flat top surface in a position level with a top end of the fin structure, and the epitaxial structures have vertical sidewalls extending upwardly from the STI structure. In some embodiments, the STI structure has a concave top surface lower than a top end of the fin structure, and the epitaxial structures have straight sidewalls in parallel with sidewalls of the fin structure and extending past the top end of the fin structure. In some embodiments, the method further includes forming a metal contact on one of the epitaxial structures, wherein a sidewall of the metal contact encloses the one of the epitaxial structures.

In some embodiments, the semiconductor device includes a (110)-orientated substrate, semiconductor sheets, gate pattern, and source/drain patterns. The semiconductor sheets are above the (110)-orientated substrate, extend in a <100> direction on the (110)-orientated substrate, and are arranged in a vertical direction. The gate pattern is across the semiconductor sheets from a top view. The source/drain patterns are on either side of the gate pattern. The source/drain patterns each has a quadrilateral profile from a cross sectional view taken along a lengthwise direction of the gate pattern. In some embodiments, a bottom portion of one of the source/drain patterns is wider than a middle portion of the one of the source/drain patterns. In some embodiments, the source/drain patterns each has a width decreasing as a distance from the (110)-orientated substrate increases. In some embodiments, the semiconductor device further includes source/drain contacts on the source/drain patterns, wherein a lateral dimension of one of the source/drain patterns is less than a lateral dimension of one of the source/drain contacts from a cross sectional view. In some embodiments, the semiconductor device further includes source/drain contacts on the source/drain patterns, wherein a sidewall of one of the source/drain patterns is steeper than a sidewall of one of the source/drain contacts from a cross sectional view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a channel region above a (110)-orientated substrate and having a length extending in a <100> direction;
epitaxial growing a plurality of source/drain regions on either side the channel region;
forming a gate structure surrounding the channel region; and
forming a plurality of source/drain contacts on the source/drain regions.

2. The method of claim 1, wherein the source/drain regions each has a quadrilateral profile from a cross sectional view taken along a lengthwise direction of the gate structure.

3. The method of claim 1, wherein a bottom portion of one of the source/drain regions is wider than a middle portion of the one of the source/drain regions from a cross sectional view taken along a lengthwise direction of the gate structure.

4. The method of claim 1, wherein the source/drain regions each has a width decreasing as a distance from the (110)-orientated substrate increases from a cross sectional view taken along a lengthwise direction of the gate structure.

5. The method of claim 1, wherein a top surface of one of the source/drain regions is in parallel with a bottom surface of the one of the source/drain regions.

6. The method of claim 1, wherein a maximal lateral dimension of one of the source/drain regions is less than a maximal lateral dimension of one of the source/drain contacts from a cross sectional view taken along a lengthwise direction of the gate structure.

7. The method of claim 1, wherein a sidewall of one of the source/drain regions is steeper than a sidewall of one of the source/drain contacts from a cross sectional view taken along a lengthwise direction of the gate structure.

8. The method of claim 1, wherein epitaxial growing the source/drain regions exhibits a growth behavior on a (100)-orientation.

9. The method of claim 1, wherein each of the source/drain regions comprise a first layer and a second layer over the first layer, the first layer comprises a first conductive type dopant, and the second layer comprises a second conductive type dopant different than the first conductive type dopant.

10. The method of claim 9, wherein the first conductive type dopant is arsenic, and the second conductive type dopant is phosphorus.

11. A method, comprising:
forming a multi-layer stack including alternating a plurality of channel layers and a plurality of sacrificial layers stacked in a vertical direction on a fin structure over a substrate having a (110) surface orientation;
forming a shallow trench isolation (STI) structure laterally surrounding the fin structure;
forming a plurality of epitaxial structures on either side of each of the channel layers, wherein the epitaxial structures each has a quadrilateral profile from a cross sectional view taken along a direction perpendicular to a lengthwise direction of the fin structure; and
replacing the sacrificial layers with a gate structure.

12. The method of claim 11, wherein the channel layers each has a length extending along a <100> direction on the (110) surface orientation.

13. The method of claim 11, wherein the STI structure has a flat top surface in a position level with a top end of the fin structure, and the epitaxial structures have vertical sidewalls extending upwardly from the STI structure.

14. The method of claim 11, wherein the STI structure has a concave top surface lower than a top end of the fin structure, and the epitaxial structures have straight sidewalls in parallel with sidewalls of the fin structure and extending past the top end of the fin structure.

15. The method of claim 11, further comprising:
forming a metal contact on one of the epitaxial structures, wherein a sidewall of the metal contact encloses the one of the epitaxial structures.

16. A semiconductor device, comprising:
a (110)-orientated substrate;
a plurality of semiconductor sheets above the (110)-orientated substrate, the semiconductor sheets extending in a <100> direction on the (110)-orientated substrate and arranged in a vertical direction;
a gate pattern across the semiconductor sheets from a top view; and
a plurality of source/drain patterns on either side of the gate pattern, wherein the source/drain patterns each has a quadrilateral profile from a cross sectional view taken along a lengthwise direction of the gate pattern.

17. The semiconductor device of claim 16, wherein a bottom portion of one of the source/drain patterns is wider than a middle portion of the one of the source/drain patterns.

18. The semiconductor device of claim 16, wherein the source/drain patterns each has a width decreasing as a distance from the (110)-orientated substrate increases.

19. The semiconductor device of claim 16, further comprising source/drain contacts on the source/drain patterns, wherein a lateral dimension of one of the source/drain patterns is less than a lateral dimension of one of the source/drain contacts from a cross sectional view.

20. The semiconductor device of claim 16, further comprising source/drain contacts on the source/drain patterns, wherein a sidewall of one of the source/drain patterns is steeper than a sidewall of one of the source/drain contacts from a cross sectional view.
